(19) United States
(12) Patent Application Publication
(10) Pub. No.: US 2023/0274977 A1
(43) Pub. Date: Aug. 31, 2023

(54) Self-Aligned Interconnect Structures and Methods of Forming the Same

(71) Applicant: Taiwan Semiconductor Manufacturing Co., Ltd., Hsinchu (TW)

(72) Inventors: Po-Hsien Cheng, Hsinchu (TW); Tze-Liang Lee, Hsinchu (TW)

(21) Appl. No.: 17/681,207

(22) Filed: Feb. 25, 2022

(51) Int. Cl. H01L 21/768

(52) U.S. Cl. CPC H01L 21/76877; H01L 21/76834; H01L 21/76802; H01L 21/76843

(57) ABSTRACT

An improved method of forming conductive features and a semiconductor device formed by the same are disclosed. Methods for forming under-bump metallurgy (UBM) structures having different surface profiles and semiconductor devices formed by the same are disclosed. In an embodiment, a method includes forming a first dielectric layer over an integrated circuit device; forming a first conductive feature in the first dielectric layer; selectively depositing a polymer layer over the first conductive feature; selectively depositing an etch stop layer over the first dielectric layer adjacent the polymer layer; removing the polymer layer to form a first opening; and forming a second conductive feature in the first opening and electrically coupled to the first conductive feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure FET) in a three-dimensional view, in accordance with some embodiments.

FIGS. 2, 3, 4, 5, 6A, 6B, 7A, 7B, 8A, 8B, 9A, 9B, 10A, 10B, 11A, 11B, 11C, 12A, 12B, 12C, 12D, 13A, 13B, 13C, 14A, 14B, 15A, 15B, 16A, 16B, 17A, 17B, 18A, 18B, 18C, 19A, 19B, 19C, 20A, 20B, 20C, 21A, 21B, and 21C are cross-sectional views of intermediate stages in the manufacturing of nanostructure FETs, in accordance with some embodiments.

FIGS. 22, 23A, 23B, 23C, 24, 25, 26, 27, 28, and 29 are cross-sectional views of intermediate stages in the manufacturing of interconnect structures for integrated circuits, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods for forming self-aligned conductive features and dielectric layers, and semiconductor devices including the same. The method includes forming a plurality of first conductive features in a first dielectric layer. A blocking film is selectively deposited over the first conductive features, without being deposited on the first dielectric layer. The blocking film may be a polymer material, which may be formed by molecular layer deposition (MLD) or the like. An etch stop layer is then deposited over the first dielectric layer adjacent the blocking film, and the blocking film is removed. A second dielectric layer is formed over the etch stop layer and the first conductive features. Photolithography and etching processes are used to form openings through the second dielectric layer exposing the first conductive features and a plurality of second conductive features are formed in the openings. Forming the blocking film over the first conductive features prevents the etch stop layer from being deposited over the first conductive features, which increases the landing area for the second conductive features and reduces contact resistance between the second conductive features and the first conductive features. Forming the blocking film by MLD helps to control the thickness of the blocking film, which allows precise control over the deposition of the blocking film and prevents lateral deposition of the etch stop layer on the first conductive features. The blocking film may be deposited to a thickness greater than the etch stop layer, which further helps to prevent lateral deposition of the etch stop layer over the first conductive features. These methods may help to improve device performance, while also reducing device defects.

Embodiments are described below in a particular context, a die comprising nanostructure FETs. Various embodiments may be applied, however, to dies comprising other types of transistors (e.g., fin field effect transistors (FinFETs), planar transistors, or the like), or other types of integrated circuit devices (e.g., resistors, capacitors, diodes, or the like), in lieu of or in combination with the nanostructure FETs.

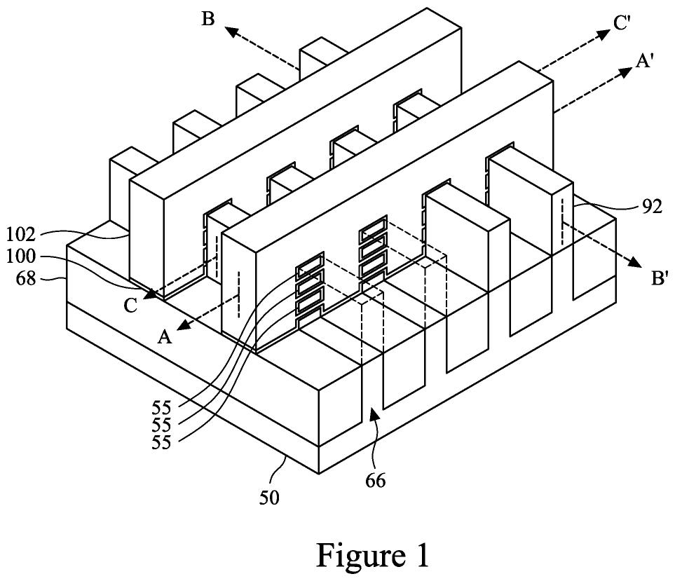

FIG. 1 illustrates an example of nanostructure FETs (e.g., nanowire FETs, nanosheet FETs (Nano-FETs), multi-bridge-channel FETs (MBCFETs), gate-all-around FETs (GAA FETs), nano-ribbon FETs, or the like) in a three-dimensional view. The nanostructure FETs comprise nanostructures 55 (e.g., nanosheets, nanowires, or the like) over fins 66 on a substrate 50 (e.g., a semiconductor substrate). The nanostructures 55 act as channel regions for the nanostructure FETs. The nanostructures 55 may include p-type nanostructures, n-type nanostructures, or a combination thereof. Isolation regions 68 are disposed between adjacent fins 66. The fins 66 may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 is illustrated as being a single, continuous material with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces and sidewalls of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nanostructure FET. Cross-section B-B′ is perpendicular to cross-section A-A′ and is parallel to a longitudinal axis of a fin 66 of the nanostructure FET and in a direction of, for example, the current flow between the epitaxial source/drain regions 92 of the nanostructure FET. Cross-section C-C′ is parallel to cross-section A-A′ and extends through the epitaxial source/drain regions 92 of the nanostructure FET. Subsequent figures refer to these reference cross-sections for clarity.

Some embodiments discussed herein are discussed in the context of nanostructure FETs formed using a gate-last process. In other embodiments, a gate-first process may be used. Some embodiments contemplate aspects used in planar devices, such as planar FETs or in fin field-effect transistors (FinFETs), or other integrated circuit devices, such as resistors, capacitors, diodes, or the like.

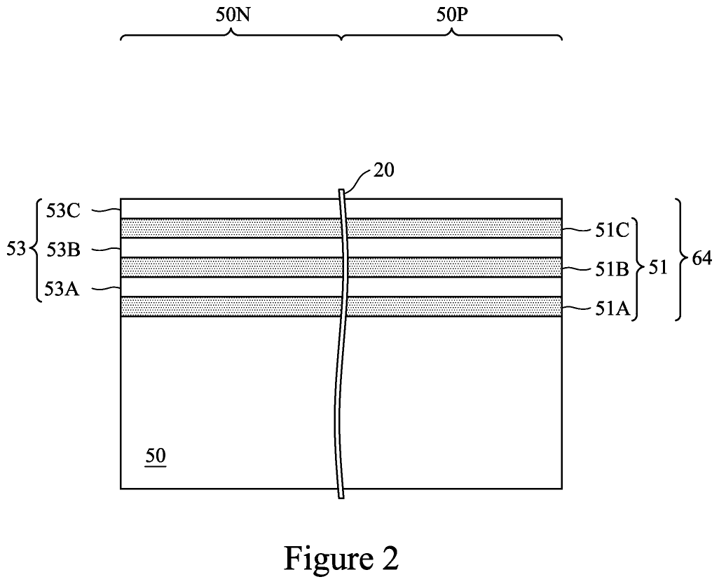

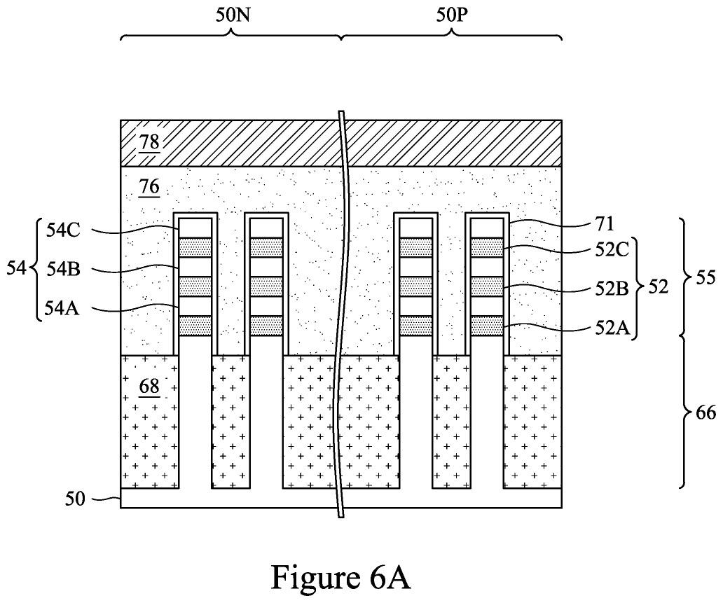

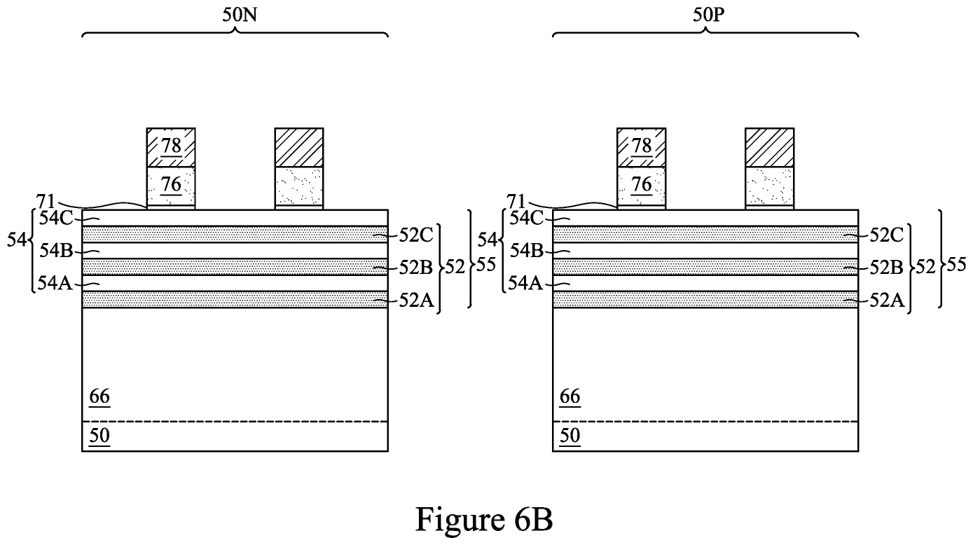

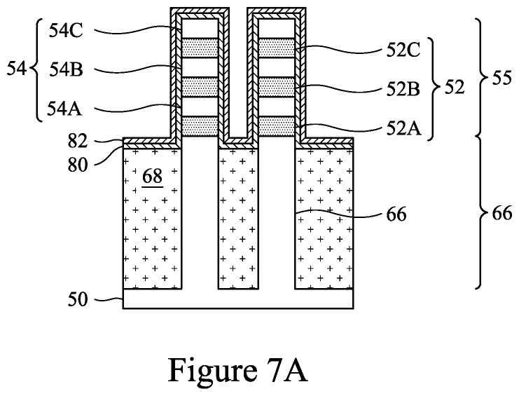

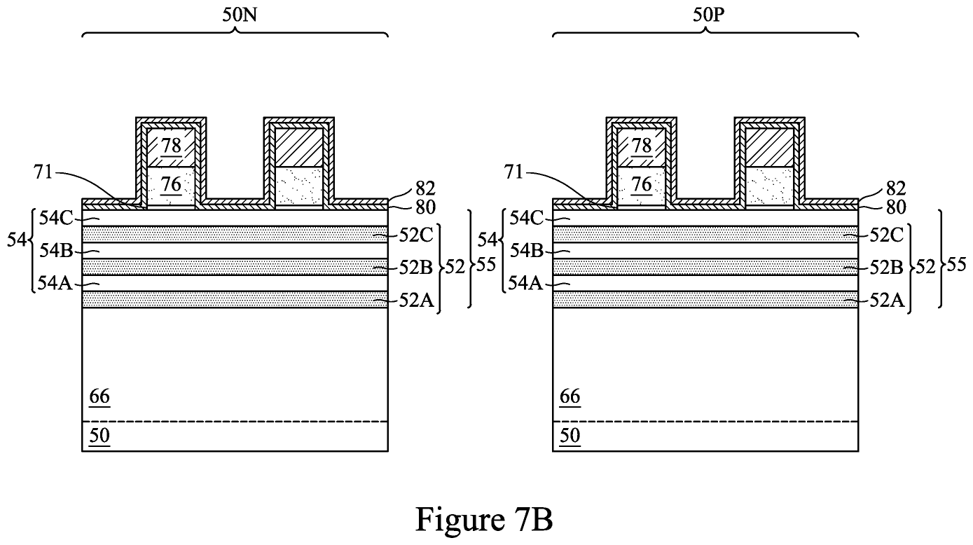

FIGS. 2 through 29 are cross-sectional views of intermediate stages in the manufacturing of nanostructure FETs, in accordance with some embodiments. FIGS. 2, 3, 4, 5, 6A, 13A, 14A, 15A, 16A, 17A, 18A, 19A, 20A, and 21A, illustrate reference cross-section A-A′ illustrated in FIG. 1. FIGS. 6B, 7B, 8B, 9B, 10B, 11B, 11C, 12B, 12D, 13B, 14B, 15B, 16B, 17B, 18B, 19B, 20B, 21B, 22, 23A, 23B, 23C, 24, 25, 26, 27, 28, and 29 illustrate reference cross-section B-B′ illustrated in FIG. 1. FIGS. 7A, 8A, 9A, 10A, 11A, 12A, 12C, 13C, 18C, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure FETs. The p-type region 50P can be for forming p-type devices, such as PMOS transistors, e.g., p-type nanostructure FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nanostructure FETs in the p-type region 50P. The first semiconductor layers 51 will be removed and the second semiconductor layers 53 will be patterned to form channel regions of nanostructure FETs in the n-type region 50N. Nevertheless, in some embodiments the first semiconductor layers 51 may be removed and the second semiconductor layers 53 may be patterned to form channel regions of nanostructure FETs in the n-type region 50N, and the second semiconductor layers 53 may be removed and the first semiconductor layers 51 may be patterned to form channel regions of nanostructure FETs in the p-type region 50P.

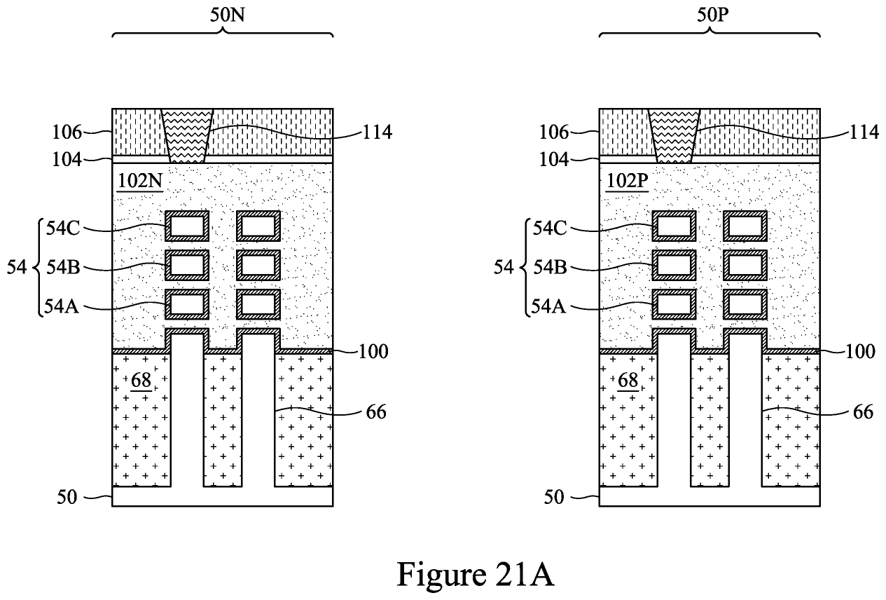

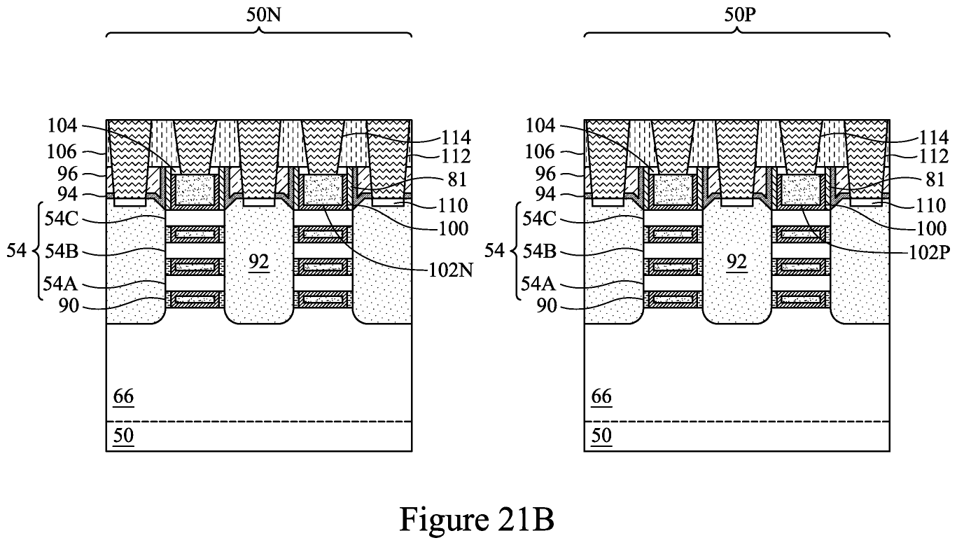

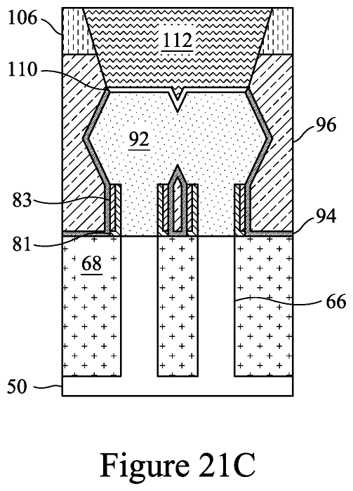

In some embodiments, the first semiconductor layers 51 may be removed and the second semiconductor layers 53 may be patterned to form channel regions of nanostructure FETs in both the n-type region 50N and the p-type region 50P. In some embodiments, the second semiconductor layers 53 may be removed and the first semiconductor layers 51 may be patterned to form channel regions of nanostructure FETs in both the n-type region 50N and the p-type region 50P. In such embodiments, the channel regions in both the n-type region 50N and the p-type region 50P may have a same material composition (e.g., silicon, or another semiconductor material) and be formed simultaneously. FIGS. 21A, 21B, and 21C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. The first semiconductor layers 51 may be formed of a first semiconductor material suitable for p-type nanostructure FETs, such as silicon germanium or the like. The second semiconductor layers 53 may be formed of a second semiconductor material suitable for n-type nanostructure FETs, such as silicon, silicon carbon, or the like. The multi-layer stack 64 is illustrated as having a bottommost semiconductor layer suitable for p-type nanostructure FETs (e.g., the first semiconductor layers 51) for illustrative purposes. In some embodiments, the multi-layer stack 64 may be formed such that the bottommost layer is a semiconductor layer suitable for n-type nanostructure FETs (e.g., the second semiconductor layers 53).

The first semiconductor materials and the second semiconductor materials may be materials having a high etch selectivity to one another. As such, the first semiconductor layers 51 formed of the first semiconductor materials may be removed without significantly removing the second semiconductor layers 53 formed of the second semiconductor materials in the n-type region 50N. This allows the second semiconductor layers 53 to be patterned to form channel regions of n-type nanostructure FETs. Similarly, the second semiconductor layers 53 formed of the second semiconductor materials may be removed without significantly removing the first semiconductor layers 51 formed of the first semiconductor materials in the p-type region 50P. This allows the first semiconductor layers 51 to be patterned to form channel regions of p-type nanostructure FETs.

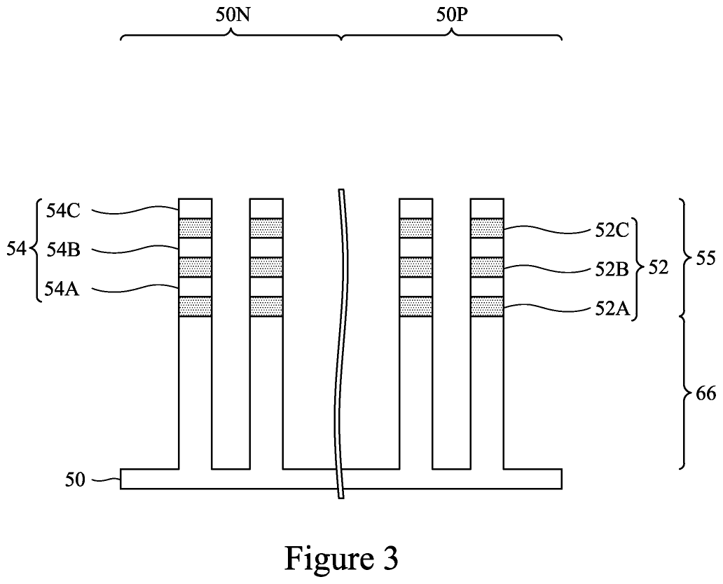

In FIG. 3, fins 66 are formed in the substrate 50 and nanostructures 55 are formed in the multi-layer stack 64. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as first nanostructures 52) from the first semiconductor layers 51 and define second nanostructures 54A-C (collectively referred to as second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers are used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater than or less than widths of the fins 66 in the p-type region 50P. Further, while each of the fins 66 and the nanostructures 55 are illustrated as having a consistent width throughout, in some embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and may be trapezoidal in shape.

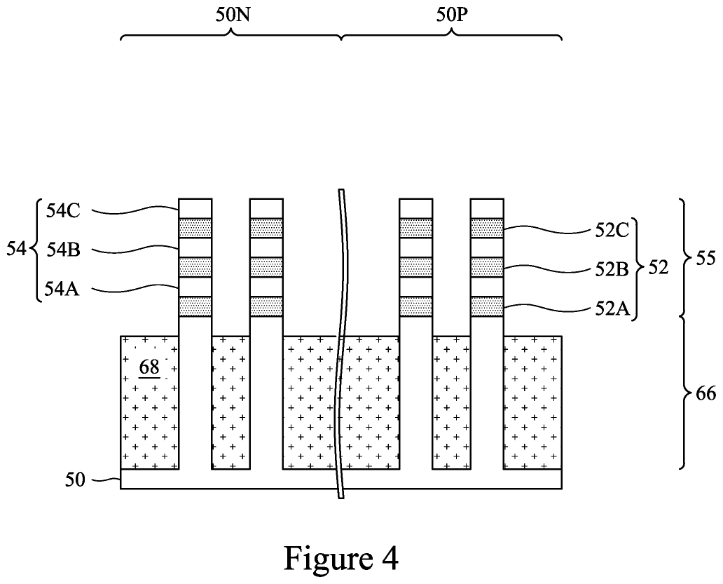

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent fins 66. The insulation material may be an oxide (such as silicon oxide), a nitride, the like, or a combination thereof. The insulation material may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments, a liner (not separately illustrated) may be formed along surfaces of the substrate 50, the fins 66, and the nanostructures 55. Thereafter, a fill material, such as those discussed above, may be formed over the liner.

A removal process is then applied to the insulation material to remove excess insulation material over the nanostructures 55. In some embodiments, a planarization process, such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that the nanostructures 55 and upper portions of the fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etch process, such as one that is selective to the material of the insulation material (e.g., etches the material of the insulation material at a faster rate than the material of the fins 66 and the nanostructures 55). An oxide removal using dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth. This may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66, the nanostructures, and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

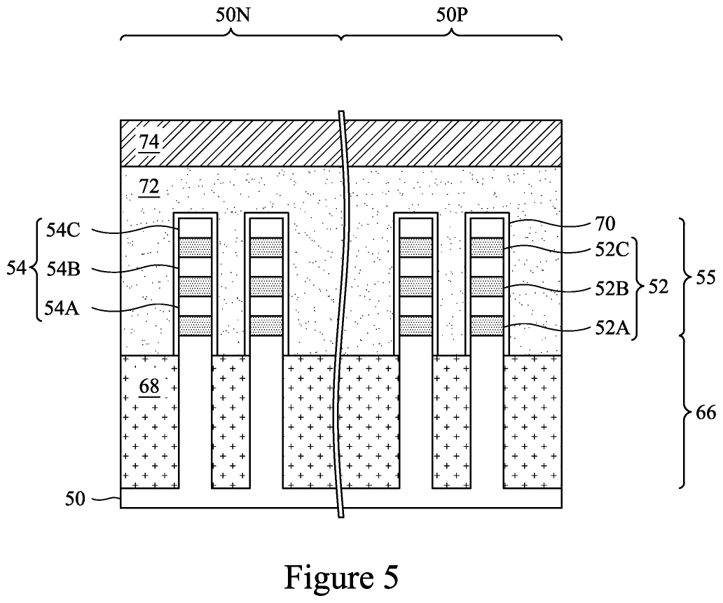

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques.

A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etch selectivity from the etching of isolation regions.

The mask layer 74 may be deposited over the dummy gate layer 72. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68. As such, the dummy dielectric layer 70 may extend between the dummy gate layer 72 and the STI regions 68.

FIGS. 6A through 21C illustrate various additional steps in the manufacturing of embodiment devices. FIGS. 7A, 8A, 9A, 10A, 11A, 12A, 12C, 13A, 13C, 14A, 15A, 19C, 20C, and 21C illustrate features in either the n-type regions 50N or the p-type regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the nanostructures 55. The pattern of the masks 78 may be used to physically separate each of the dummy gates 76 from adjacent dummy gates 76. The dummy gates 76 may also have a lengthwise direction substantially perpendicular to the lengthwise direction of respective fins 66. The masks 78, the dummy gates 76, and the dummy gate dielectrics 71 may be collectively referred to as “dummy gate structures.”

In FIGS. 7A and 7B, a first spacer layer 80 and a second spacer layer 82 are formed over dummy gate structures, the nanostructures 55, and the STI regions 68. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the nanostructures 55 and the masks 78; and sidewalls of the dummy gates 76, the dummy gate dielectrics 71, and the fins 66. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P. Appropriate type (e.g., p-type) impurities may be implanted into the exposed fins 66 and the nanostructures 55 in the p-type region 50P. The mask may then be removed. Subsequently, a mask, such as a photoresist, may be formed over the p-type region 50P while exposing the n-type region 50N. Appropriate type impurities (e.g., n-type) may be implanted into the exposed fins 66 and the nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

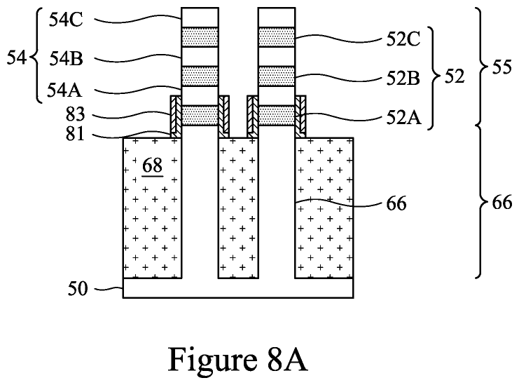

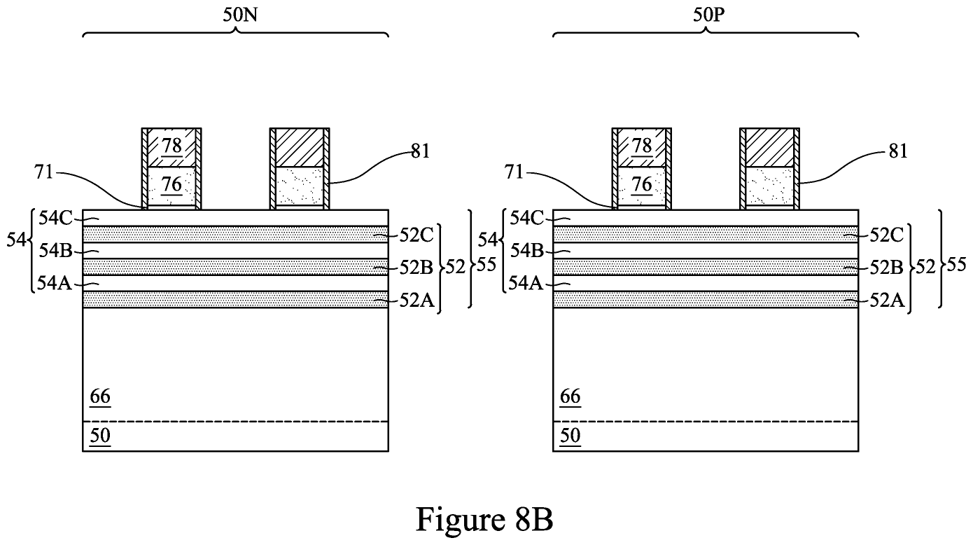

In FIGS. 8A and 8B, the first spacer layer 80 and the second spacer layer 82 (see FIGS. 7A and 7B) are etched to form first spacers 81 and second spacers 83. As will be discussed in greater detail below, the first spacers 81 and the second spacers 83 act to self-align subsequently formed source drain regions, as well as to protect sidewalls of the fins 66 and/or the nanostructures 55 during subsequent processing. The first spacer layer 80 and the second spacer layer 82 may be etched using a suitable etch process, such as an isotropic etch process (e.g., a wet etch process), an anisotropic etch process (e.g., a dry etch process), or the like. In some embodiments, the material of the second spacer layer 82 has a different etch rate than the material of the first spacer layer 80, such that the first spacer layer 80 may act as an etch stop layer when patterning the second spacer layer 82 and the second spacer layer 82 may act as a mask when patterning the first spacer layer 80. For example, the second spacer layer 82 may be etched using an anisotropic etch process wherein the first spacer layer 80 acts as an etch stop layer. Remaining portions of the second spacer layer 82 form second spacers 83, as illustrated in FIG. 8A. The second spacers 83 then act as a mask while etching exposed portions of the first spacer layer 80, thereby forming first spacers 81 as illustrated in FIGS. 8A and 8B.

As illustrated in FIG. 8A, the first spacers 81 and the second spacers 83 are disposed on sidewalls of the fins 66 and/or the nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and only the first spacers 81 are disposed on sidewalls of the masks 78, the dummy gates 76, and the dummy dielectric layers 60. In some embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

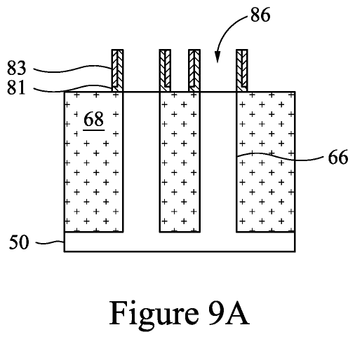

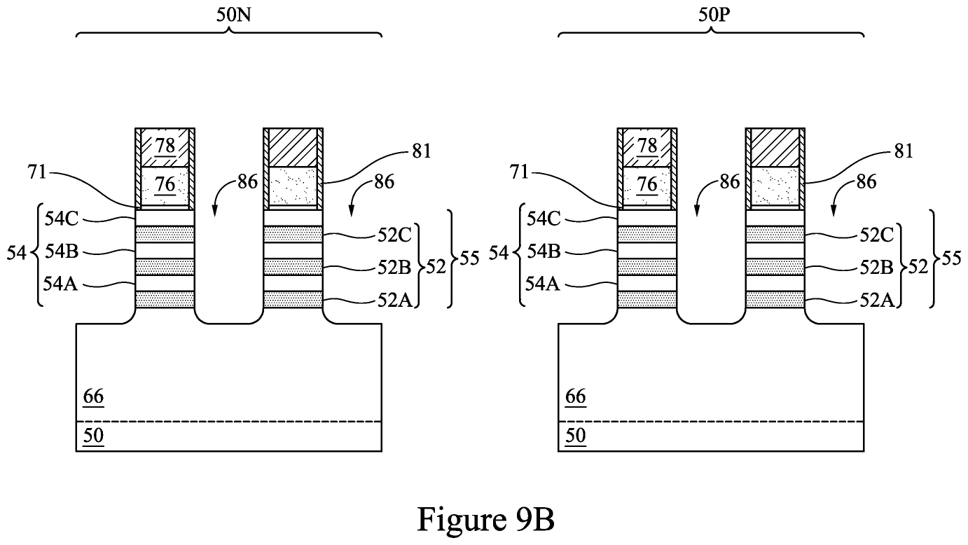

In FIGS. 9A and 9B, first recesses 86 are formed in the nanostructures 55, the fins 66, and the substrate 50. Epitaxial source/drain regions will be subsequently formed in the first recesses 86. The first recesses 86 may extend through the first nanostructures 52, the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed above the top surfaces of the STI regions 68, below the top surfaces of the STI regions 68, or the like. The first recesses 86 may be formed by etching the nanostructures 55, the fins 66, and the substrate 50 using an anisotropic etch processes, such as RIE, NBE, or the like. The first spacers 81, the second spacers 83, and the masks 78 mask portions of the nanostructures 55, the fins 66, and the substrate 50 during the etch processes used to form the first recesses 86. A single etch process or multiple etch processes may be used to etch each layer of the nanostructures 55, the fins 66, and/or the substrate 50. Timed etch processes may be used to stop the etching of the first recesses 86 after the first recesses 86 reach a desired depth.

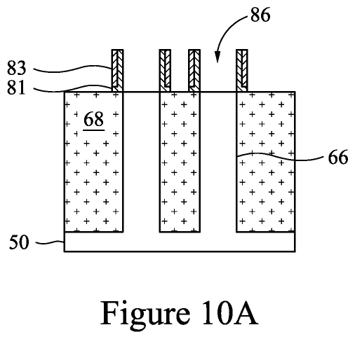

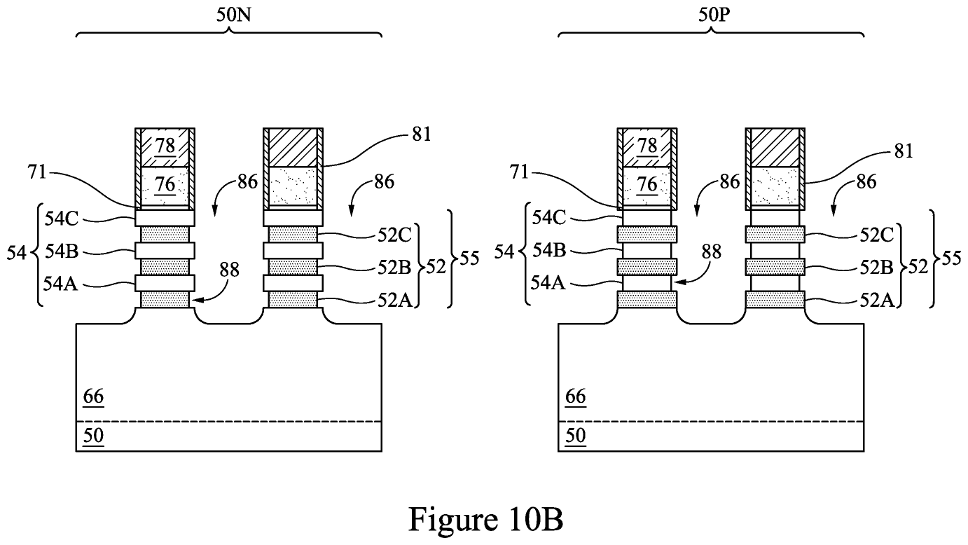

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 64 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 adjacent the sidewall recesses 88 are illustrated as being straight in FIG. 10B, the sidewalls may be concave or convex. The sidewalls may be etched using isotropic etch processes, such as a wet etch or the like. The p-type region 50P may be protected using a mask (not separately illustrated), while etchants selective to the first semiconductor materials are used to etch the first nanostructures 52. As such, the second nanostructures 54 and the substrate 50 in the n-type region 50N remain relatively un-etched as compared to the first nanostructures 52. Similarly, the n-type region 50N may be protected using a mask (not separately illustrated), while etchants selective to the second semiconductor materials are used to etch the second nanostructures 54. As such, the first nanostructures 52 and the substrate 50 in the p-type region 50P remain relatively un-etched as compared to the second nanostructures 54. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N. A wet or dry etch process with hydrogen fluoride, another fluorine-based etchant, or the like may be used to etch sidewalls of the second nanostructures 54 in the p-type region 50P.

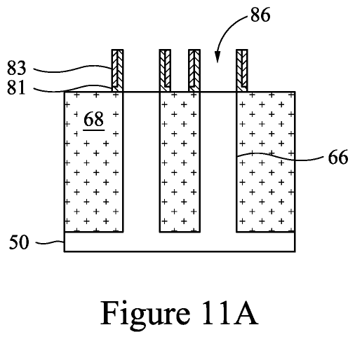

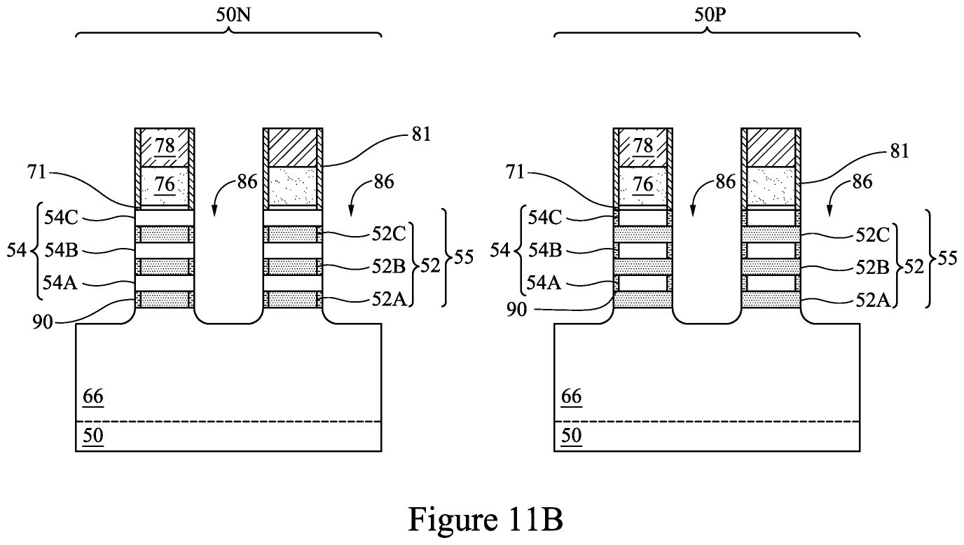

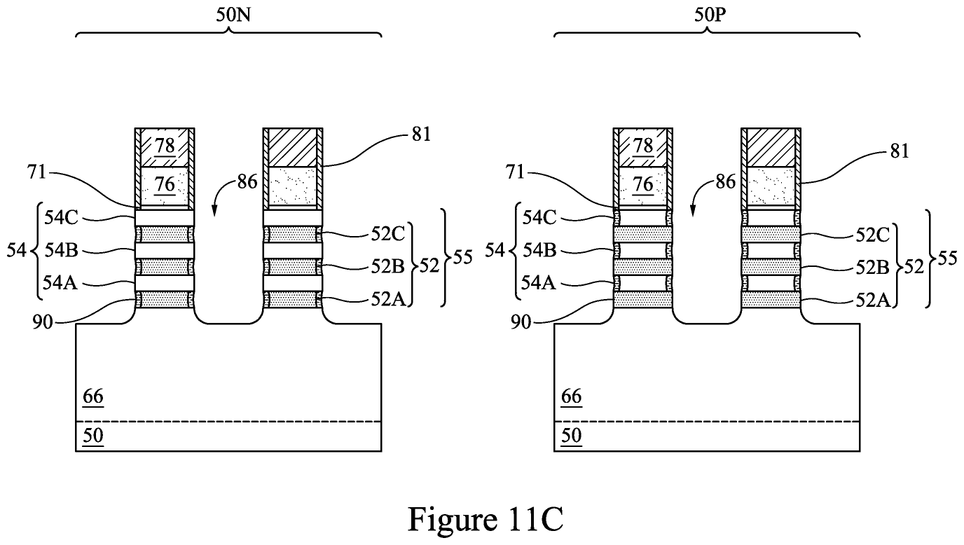

In FIGS. 11A through 11C, first inner spacers 90 are formed in the sidewall recesses 88. The first inner spacers 90 may be formed by depositing an inner spacer layer (not separately illustrated) over the structures illustrated in FIGS. 10A and 10B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may be anisotropically etched to form the first inner spacers 90, using a process such as RIE, NBE, or the like.

Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52. Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Further in FIG. 11C, sidewalls of the second nanostructures 54 are concave, outer sidewalls of the first inner spacers 90 are concave, and the first inner spacers 90 are recessed from sidewalls of the first nanostructures 52 in the p-type region 50P.

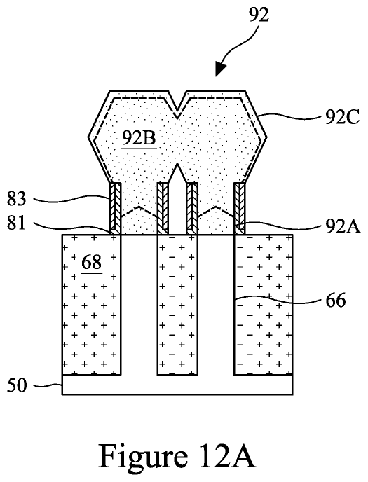

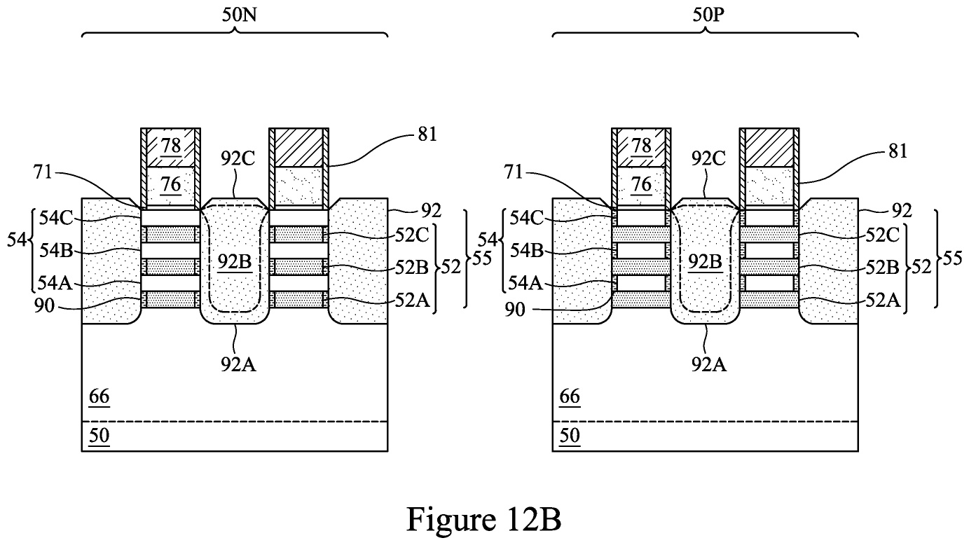

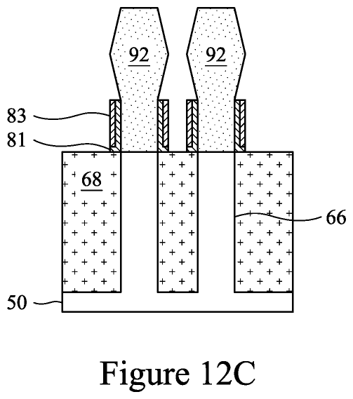

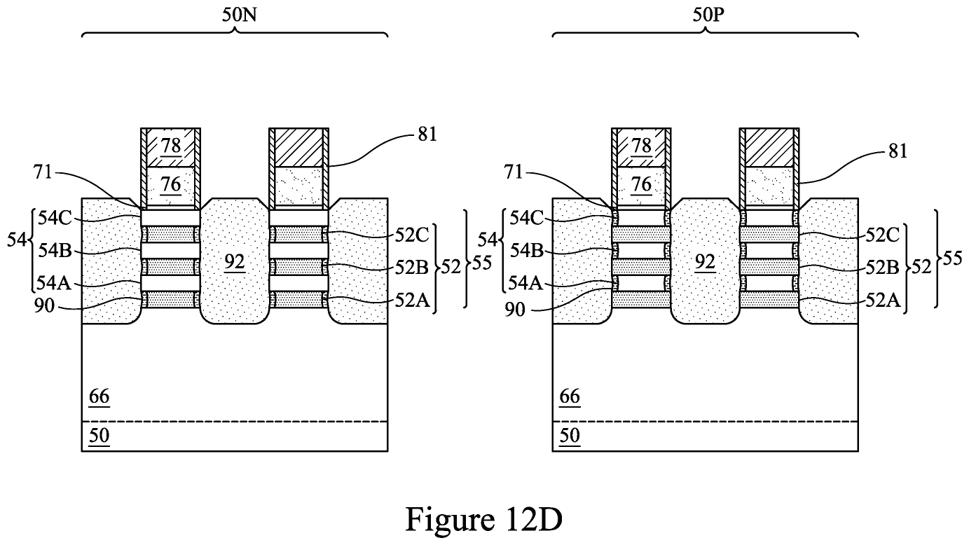

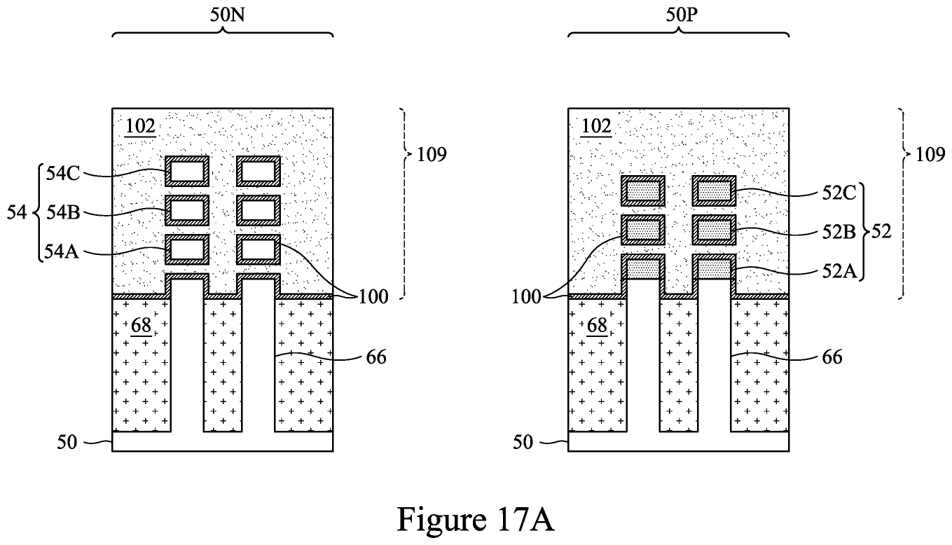

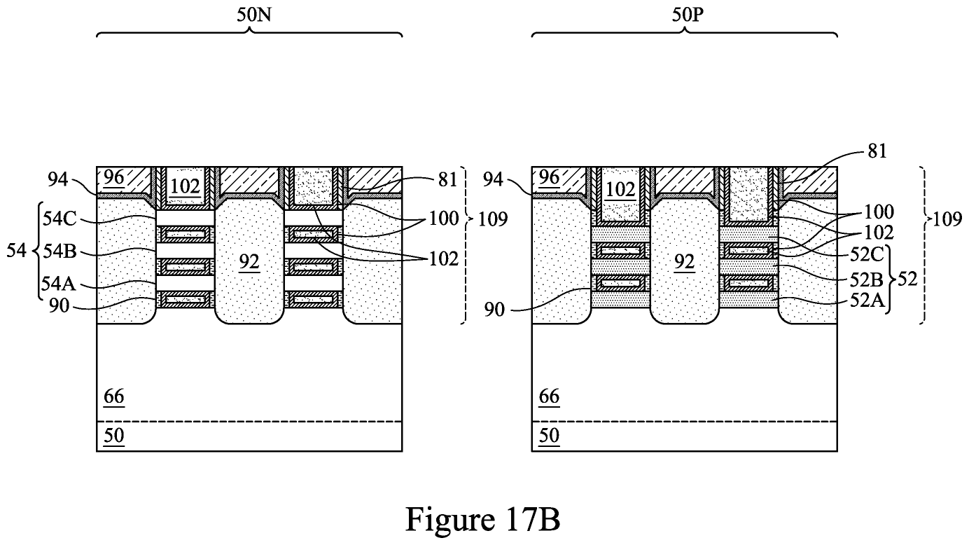

The first inner spacers 90 act as isolation features between subsequently formed source/drain regions (such as the epitaxial source/drain regions 92, discussed below with respect to FIGS. 12A through 12D) and gate structures (such as the gate structures including the gate dielectric layers 100 and the gate electrodes 102, discussed below with respect to FIGS. 17A and 17B). The first inner spacers 90 may be also prevent damage to the epitaxial source/drain regions 92 by subsequent etching processes, such as etching processes used to form the gate structures including the gate dielectric layers 100 and the gate electrodes 102.

In FIGS. 12A through 12D, epitaxial source/drain regions 92 (which may include a first semiconductor material layer 92A, a second semiconductor material layer 92B, and a third semiconductor material layer 92C) are formed in the first recesses 86 (illustrated in FIGS. 11B and 11C). In some embodiments, the epitaxial source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each of the dummy gates 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by appropriate lateral distances to prevent shorts between the epitaxial source/drain regions 92 and subsequently formed gate structures (such as the gate structures including the gate dielectric layers 100 and the gate electrodes 102, discussed below with respect to FIGS. 17A and 17B).

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nanostructure FETs. For example, in embodiments in which the second nanostructures 54 are silicon, the epitaxial source/drain regions 92 may include materials exerting a tensile strain on the second nanostructures 54, such as silicon, silicon carbide, phosphorous-doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nanostructure FETs. For example, in embodiments in which the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the nanostructures 55 and may have facets.

The epitaxial source/drain regions 92, the nanostructures 55, the fins 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for the source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nanostructure FET to merge, as illustrated by FIG. 12A. In other embodiments, adjacent epitaxial source/drain regions 92 remain separated after the epitaxy process is completed, as illustrated by FIG. 12C. In the embodiments illustrated in FIGS. 12A and 12C, the first spacers 81 may be formed extending to top surfaces of the STI regions 68, thereby blocking the epitaxial growth. In some embodiments, the first spacers 81 may cover portions of the sidewalls of the nanostructures 55, further blocking the epitaxial growth. In some embodiments, the spacer etch used to form the first spacers 81 may be adjusted to remove the spacer material, allowing the epitaxial source/drain regions 92 to extend to the surfaces of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

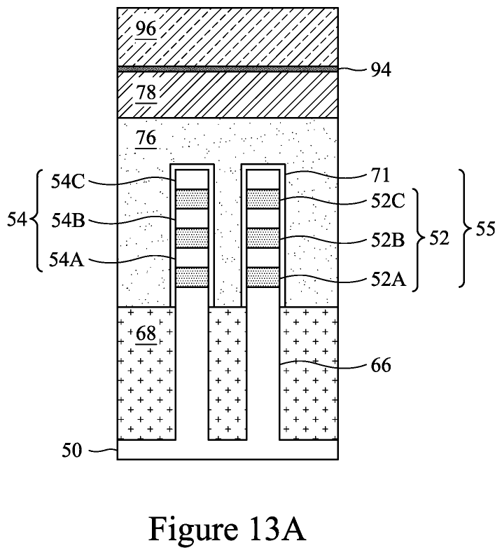

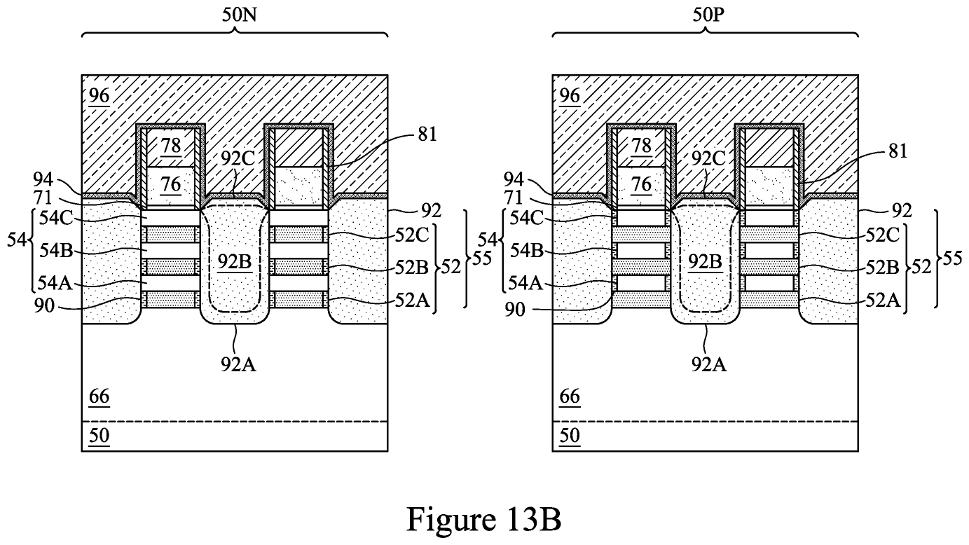

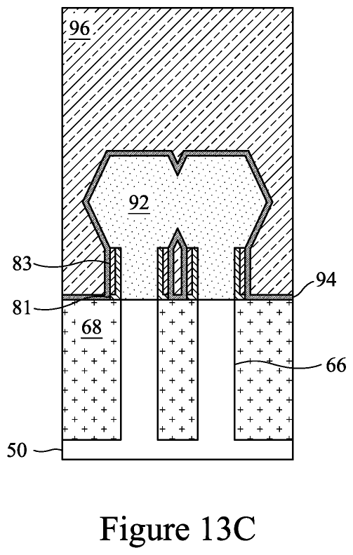

In FIGS. 13A through 13C, a contact etch stop layer (CESL) 94 and a first interlayer dielectric (ILD) 96 are deposited over the epitaxial source/drain regions 92, the dummy gate structures, the first spacers 81, and the STI regions 68. The CESL 94 may comprise a dielectric material, such as, silicon nitride, silicon oxide, silicon oxynitride, or the like, having a different etch rate than the material of the overlying first ILD 96. The CESL 94 may be deposited by ALD, CVD, or the like. The CESL 94 may be optional and may be omitted in some embodiments. The first ILD 96 may be formed of a dielectric material, and may be deposited by any suitable method, such as CVD, plasma-enhanced CVD (PECVD), or FCVD. Suitable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

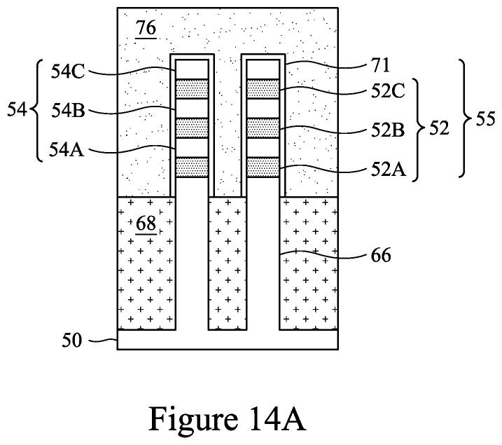

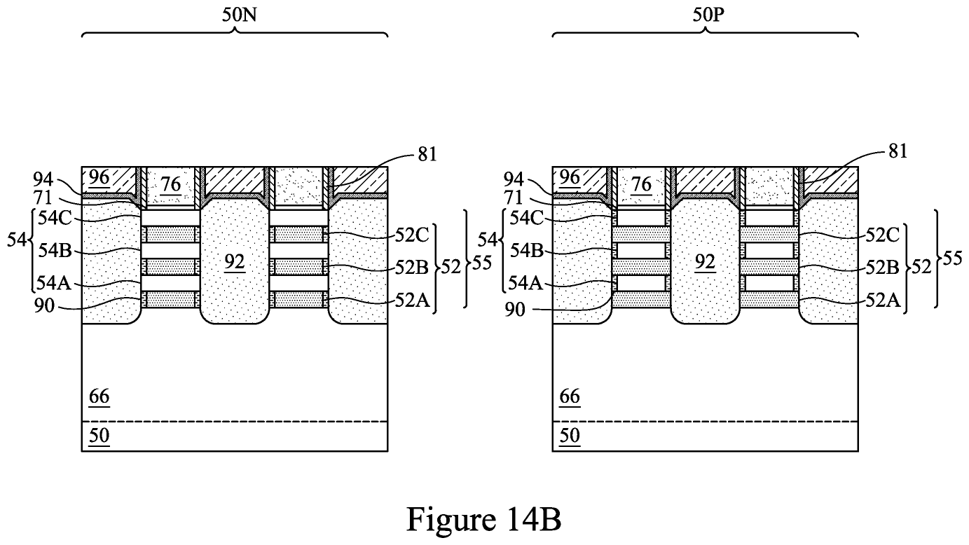

In FIGS. 14A and 14B, a planarization process, such as a CMP, is performed to level top surfaces of the first ILD 96 with top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, the CESL 94, and the first ILD 96 are level with one another (within process variations). Accordingly, the top surfaces of the dummy gates 76 are exposed through the first ILD 96 and the CESL 94. In some embodiments, the masks 78 may remain, in which case the planarization process levels the top surfaces of the first ILD 96 and the CESL 94 with top surfaces of the masks 78 and the first spacers 81.

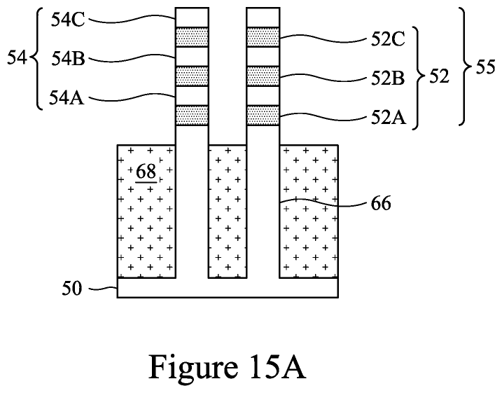

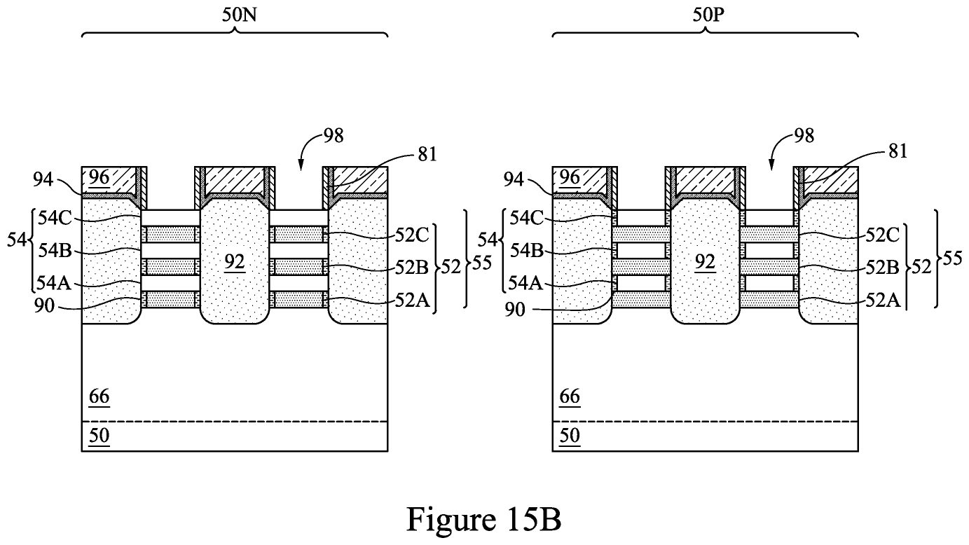

In FIGS. 15A and 15B, the dummy gates 76, the dummy gate dielectrics 71, and the masks 78, if present, are removed, forming second recesses 98. In some embodiments, the dummy gates 76 and the dummy gate dielectrics 71 are removed by one or more etch processes, such as anisotropic dry etch processes. The etch processes may include a dry etch process using reaction gas(es) that selectively etch the dummy gates 76 (at a faster rate than the first ILD 96, the CESL 94, or the first spacers 81). Each of the second recess 98 exposes and/or overlies portions of nanostructures 55, which act as channel regions in subsequently completed nanostructure FETs. The portions of the nanostructures 55 that act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

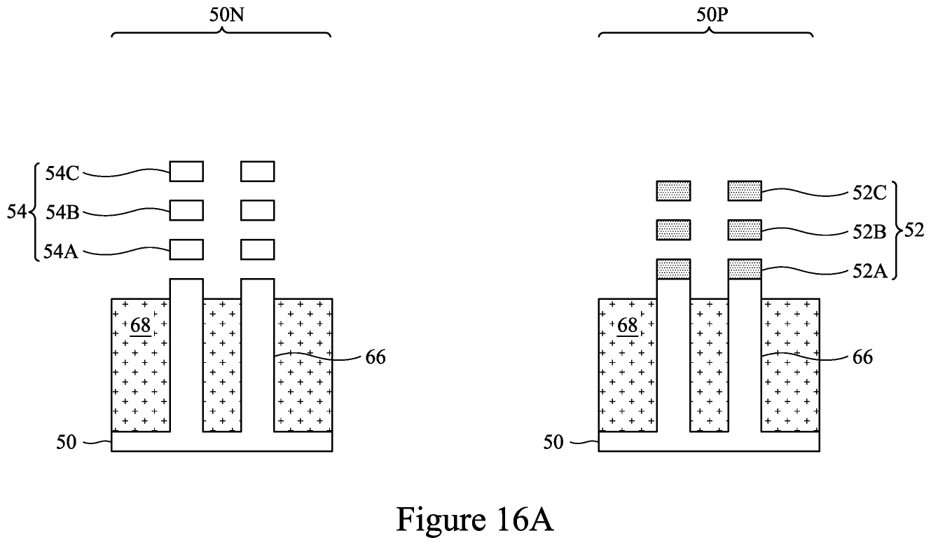

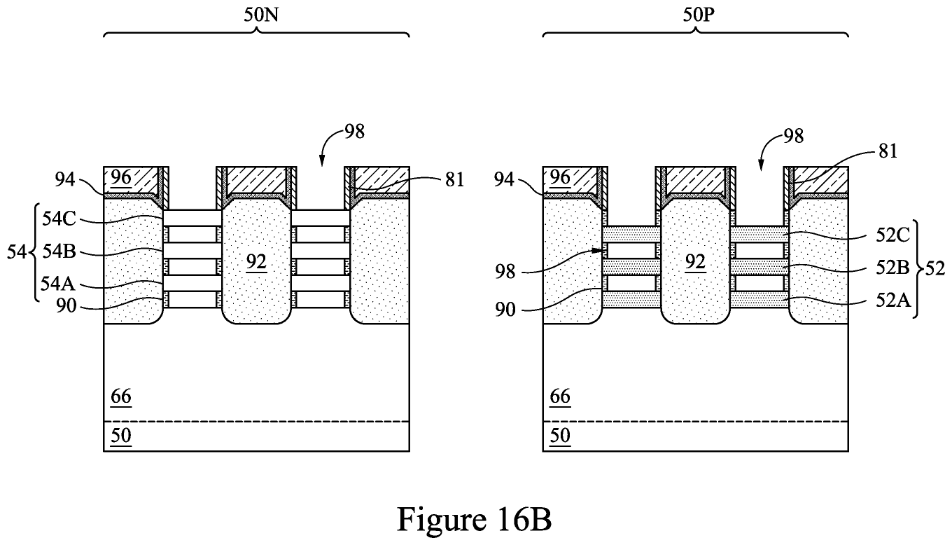

In FIGS. 16A and 16B, the first nanostructures 52 in the n-type region 50N and the second nanostructures 54 in the p-type region 50P are removed extending the second recesses 98. The first nanostructures 52 may be removed by forming a mask (not separately illustrated) over the p-type region 50P and performing an isotropic etching process, such as wet etching or the like, using etchants which are selective to the materials of the first nanostructures 52. The second nanostructures 54, the fins 66, the substrate 50, the STI regions 68, the first ILD 96, and the CESL 94 remain relatively un-etched as compared to the first nanostructures 52. In embodiments in which the first nanostructures 52 include, e.g., SiGe, and the second nanostructures 54 include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not separately illustrated) over the n-type region 50N and performing an isotropic etching process such as wet etching or the like using etchants which are selective to the materials of the second nanostructures 54. The first nanostructures 52, the fins 66, the substrate 50, the STI regions 68, the first ILD 96, and the CESL 94 remain relatively un-etched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously. For example, the first nanostructures 52 in both the n-type region 50N and the p-type region 50P may be removed, or the second nanostructures 54 in both the n-type region 50N and the p-type region 50P may be removed. In such embodiments, channel regions of n-type nanostructure FETs and p-type nanostructure FETs may have a same material composition, such as silicon, silicon germanium, or the like. FIGS. 21A through 21C illustrate a structure resulting from embodiments in which channel regions in both the p-type region 50P and the n-type region 50N are provided by the second nanostructures 54 and comprise silicon.

In FIGS. 17A and 17B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the fins 66 and on top surfaces, sidewalls, and bottom surfaces of the second nanostructures 54. In the p-type region 50P, the gate dielectric layers 100 may be formed on top surfaces and sidewalls of the fins 66, on top surfaces and sidewalls of the first nanostructures 52A, and on top surfaces, sidewalls, and bottom surfaces of the first nanostructures 52B and 52C. The gate dielectric layers 100 may also be deposited on top surfaces of the first ILD 96, the CESL 94, and the STI regions 68; on top surfaces and sidewalls of the first spacers 81; and on sidewalls of the first inner spacers 90.

In some embodiments, the gate dielectric layers 100 comprise one or more dielectric layers, such as an oxide, a metal oxide, the like, or combinations thereof. For example, the gate dielectric layers 100 may comprise a silicon oxide layer and a metal oxide layer over the silicon oxide layer. In some embodiments, the gate dielectric layers 100 include a high-k dielectric material, and the gate dielectric layers 100 may have a k-value greater than about 7.0. The gate dielectric layers 100 may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100 and fill remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. Although single-layer gate electrodes 102 are illustrated in FIGS. 17A and 17B, the gate electrodes 102 may comprise any number of liner layers, any number of work function tuning layers, and a fill material. Any combination of the layers that make up the gate electrodes 102 may be deposited in the n-type region 50N between adjacent ones of the second nanostructures 54 and between the second nanostructures 54A and the fins 66. Further, any combination of the layers that make up the gate electrodes 102 may be deposited in the p-type region 50P between adjacent ones of the first nanostructures 52.

The formation of the gate dielectric layers 100 in the n-type region 50N and the p-type region 50P may occur simultaneously, such that the gate dielectric layers 100 in each region are formed from the same materials. In some embodiments, the gate dielectric layers 100 in each region may be formed by distinct processes, such that the gate dielectric layers 100 may be different materials and/or have a different number of layers. The formation of the gate electrodes 102 in the n-type region 50N and the p-type region 50P may occur simultaneously such that the gate electrodes 102 in each region are formed from the same materials. The gate electrodes 102 in each region may be formed by distinct processes, such that the gate electrodes 102 may be different materials and/or have a different number of layers. Various masking steps may be used to mask and expose appropriate regions when using distinct processes.

After the second recesses 98 are filled, a planarization process, such as a CMP, may be performed to remove excess portions of the gate dielectric layers 100 and the material of the gate electrodes 102, which excess portions are over top surfaces of the first ILD 96, the CESL 94, and the first spacers 81. The remaining portions of material of the gate electrodes 102 and the gate dielectric layers 100 form replacement gate structures of the resulting nanostructure FETs. The gate electrodes 102 and the gate dielectric layers 100 may be collectively referred to as “gate structures.” The epitaxial source/drain regions 92, the first nanostructures 52 or second nanostructures 54, and the gate structures (including the gate dielectric layers 100 and the gate electrodes 102) may collectively be referred to as transistor structures 109.

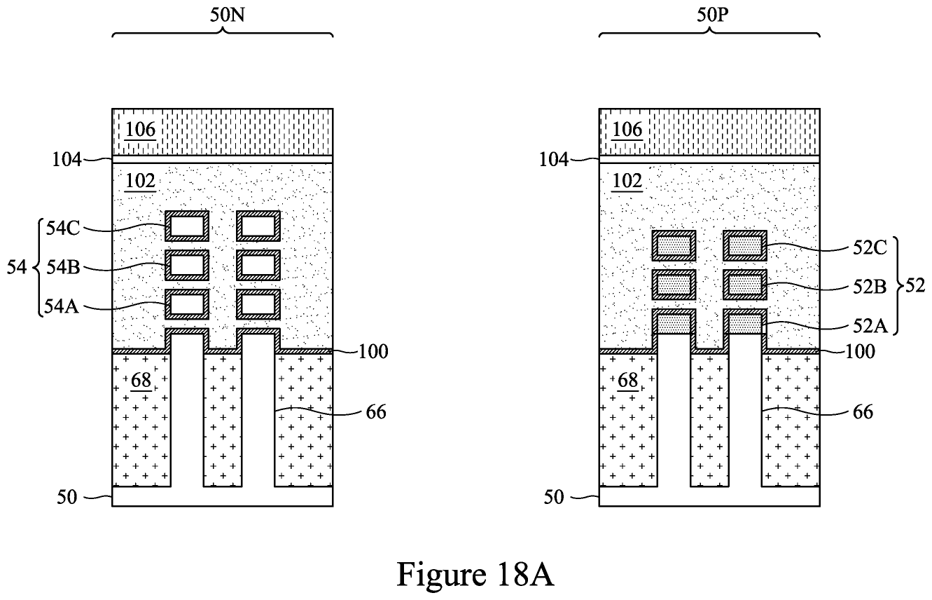

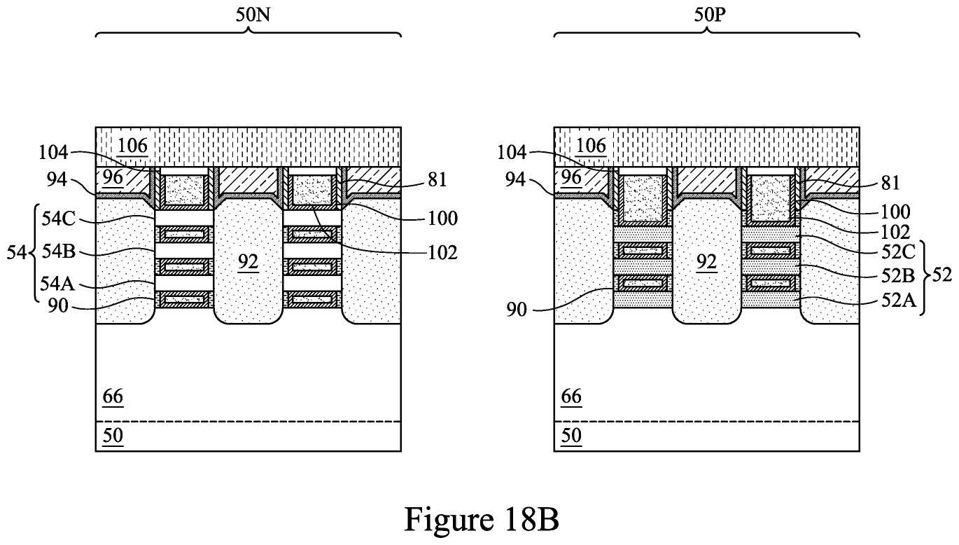

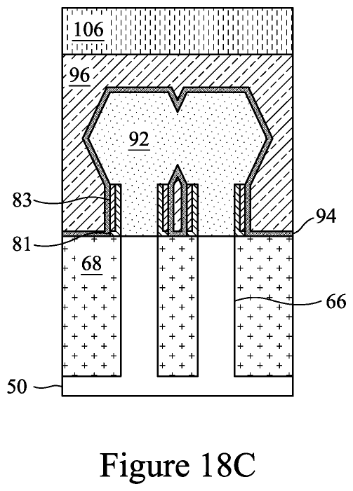

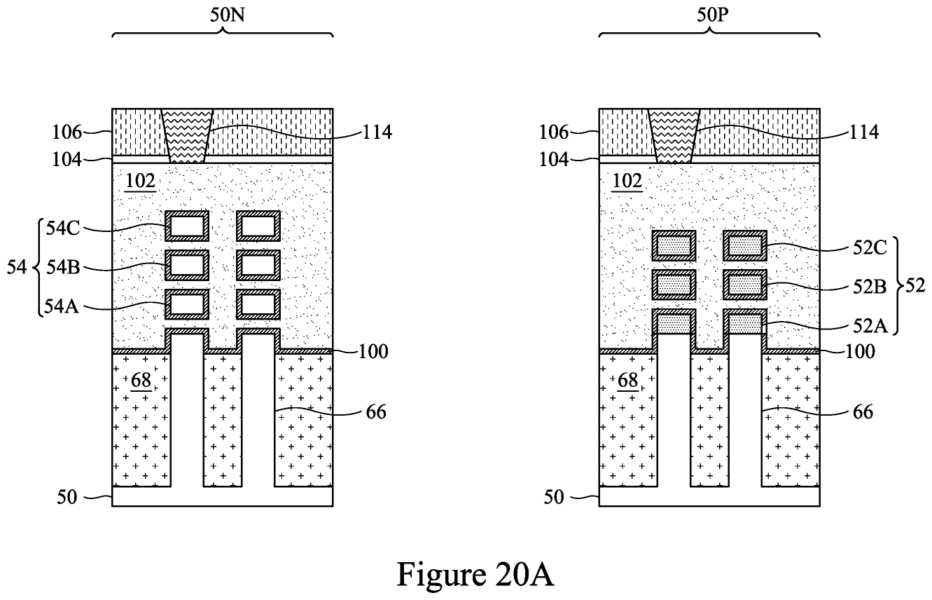

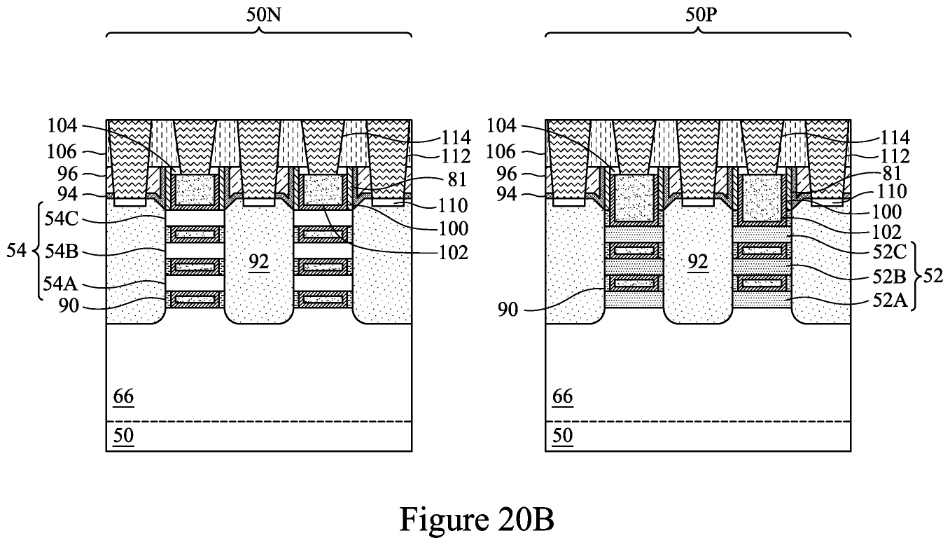

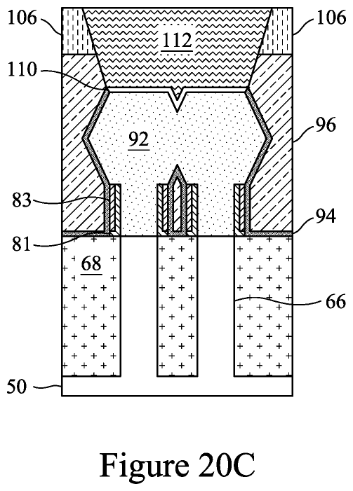

In FIGS. 18A through 18C, the gate structures (including the gate dielectric layers 100 and the corresponding overlying gate electrodes 102) are recessed, so that recesses are formed directly over the gate structures and between opposing portions of first spacers 81. A gate mask 104 comprising one or more layers of dielectric material, such as silicon nitride, silicon oxynitride, or the like, is filled in the recesses, followed by a planarization process to remove excess portions of the dielectric material extending over the first ILD 96, the CESL 94, and the first spacers 81. Subsequently formed gate contacts (such as the gate contacts 114, discussed below with respect to FIGS. 20A through 20C) penetrate through the gate mask 104 to contact top surfaces of the recessed gate electrodes 102.

Further in FIGS. 18A through 18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

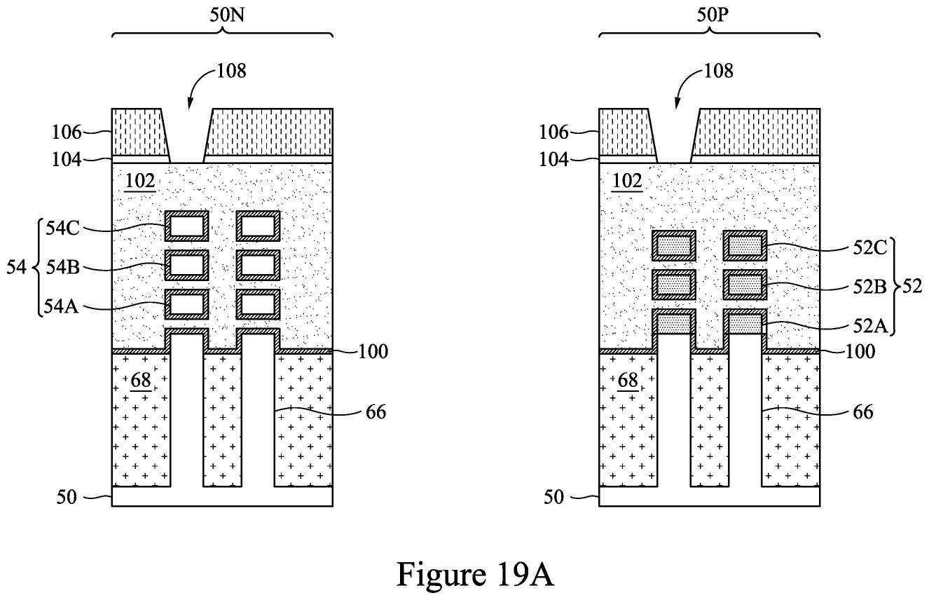

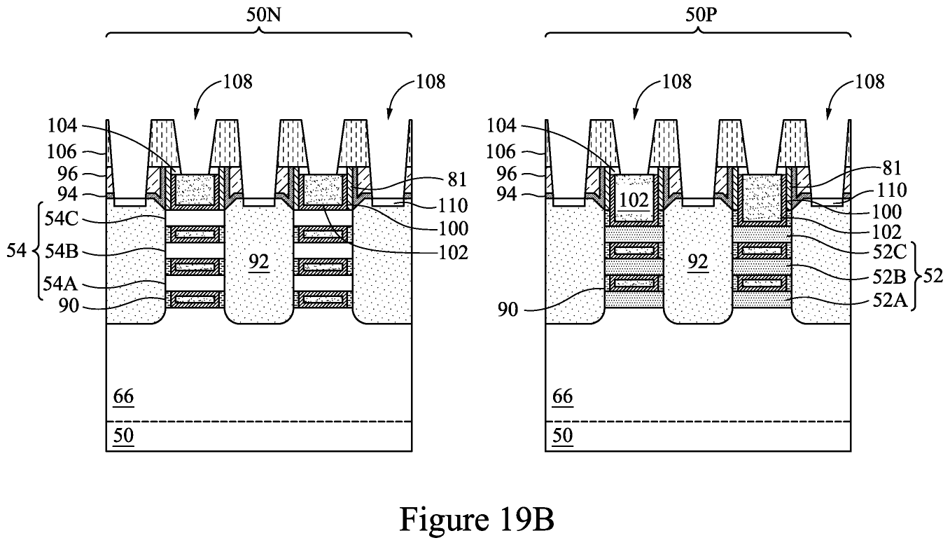

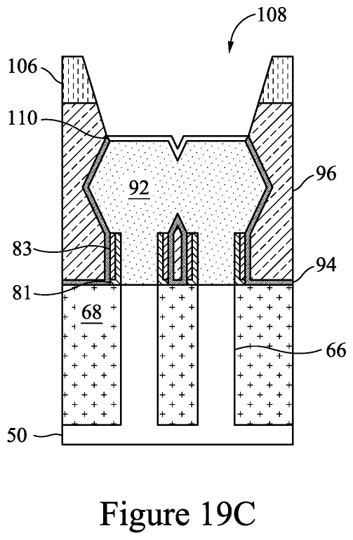

In FIGS. 19A through 19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may be etched through the CESL 94 using a third etching process. A mask, such as a photoresist, may be formed and patterned over the second ILD 106 to mask portions of the second ILD 106 from the first etching process, the second etching process, and the third etching process. In some embodiments, the etching processes may over-etch, and therefore, the recesses may extend into the epitaxial source/drain regions 92. Bottom surfaces of the recesses may be level with (e.g., at a same level, or having a same distance from the substrate 50), or lower than (e.g., closer to the substrate 50) top surfaces of the epitaxial source/drain regions 92. Although FIG. 19B illustrates the third recesses 108 as exposing the epitaxial source/drain regions 92 and the gate structure in a same cross section, in some embodiments, the epitaxial source/drain regions 92 and the gate structure may be exposed in different cross-sections. This reduces the risk of shorting subsequently formed contacts.

After the third recesses 108 are formed, silicide regions 110 are formed over the epitaxial source/drain regions 92. In some embodiments, the silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92. A thermal anneal process is then performed to form the silicide regions 110. Un-reacted portions of the deposited metal are then removed, e.g., by an etching process. Although the silicide regions 110 are referred to as silicide regions, the silicide regions 110 may also be germanide regions, or silicon germanide regions (e.g., regions comprising silicide and germanide). In an embodiment, the silicide regions 110 comprise TiSi, and have thicknesses ranging from about 2 nm to about 10 nm.

In FIGS. 20A through 20C, source/drain contacts 112 and gate contacts 114 (each of which may also be referred to as contact plugs) are formed in the third recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and each of the source/drain contacts 112 and the gate contacts 114 is electrically coupled to the underlying conductive feature (e.g., the underlying gate structures and/or silicide regions 110 in the illustrated embodiment). The gate contacts 114 are electrically coupled to the gate structures and the source/drain contacts 112 are electrically coupled to the epitaxial source/drain regions 92 through the silicide regions 110. The barrier layer may include titanium, titanium nitride, tantalum, tantalum nitride, or the like. The conductive material 118 may include copper, a copper alloy, silver, gold, tungsten, cobalt, aluminum, nickel, or the like. A planarization process, such as a CMP, may be performed to remove excess material of the barrier layer and the conductive material from surfaces of the second ILD 106.

FIGS. 21A through 21C illustrate cross-sectional views of a device according to some alternative embodiments. FIG. 21A illustrates reference cross-section A-A′ illustrated in FIG. 1. FIG. 21B illustrates reference cross-section B-B′ illustrated in FIG. 1. FIG. 21C illustrates reference cross-section C-C′ illustrated in FIG. 1. In FIGS. 21A through 21C, like reference numerals indicate like elements formed by like processes as the structure of FIGS. 20A through 20C. However, in FIGS. 21A through 21C, channel regions in the n-type region 50N and the p-type region 50P comprise a same material. For example, the second nanostructures 54, which comprise silicon, provide channel regions for p-type nanostructure FETs in the p-type region 50P and for n-type nanostructure FETs in the n-type region 50N. The structure of FIGS. 21A through 21C may be formed, for example, by removing the first nanostructures 52 from both the p-type region 50P and the n-type region 50N simultaneously; depositing the gate dielectric layers 100 over top surfaces and side surfaces of the fins 66 and over top surfaces, side surfaces, and bottom surfaces of the second nanostructures 54 in the p-type region 50P and the n-type region 50N; and depositing gate electrodes 102P (e.g., gate electrodes suitable for p-type nanostructure FETs) over the gate dielectric layers 100 in the p-type region 50P and depositing gate electrodes 102N (e.g., gate electrodes suitable for n-type nanostructure FETs) over the gate dielectric layers in the n-type region 50N. Materials of the epitaxial source/drain regions 92 in the n-type region 50N may be different from materials of the epitaxial source/drain regions 92 in the p-type region 50P, as explained above.

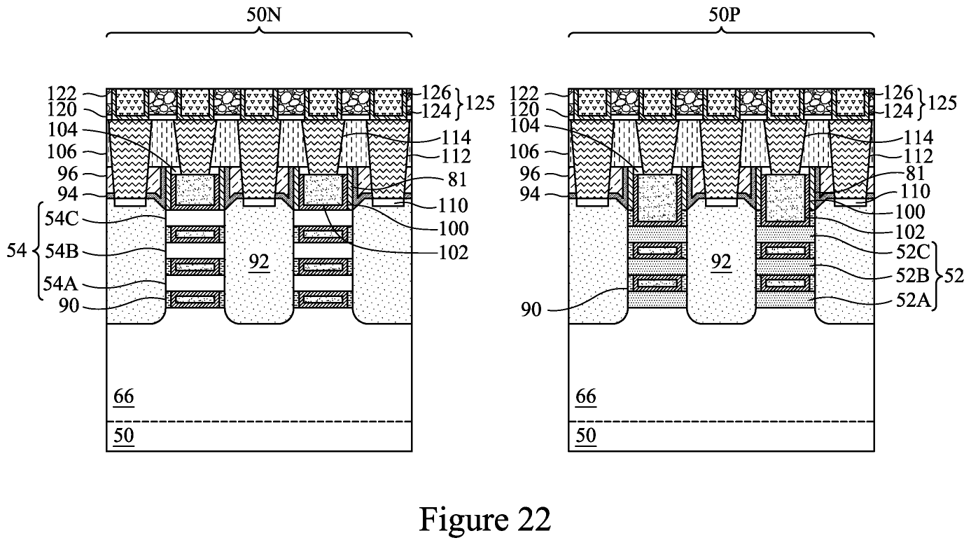

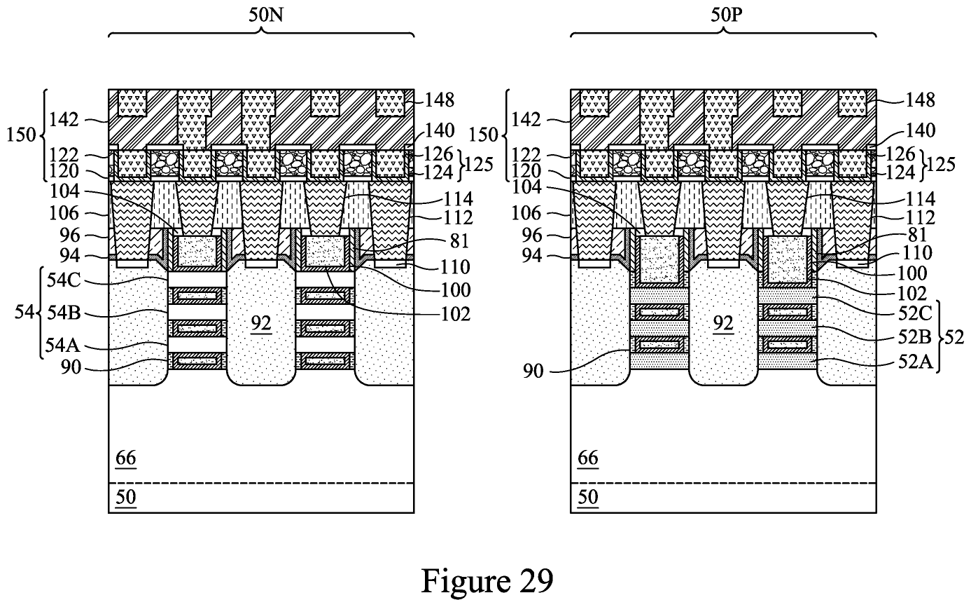

In FIGS. 22 through 29, an interconnect structure 150 (illustrated in FIG. 29) is formed over the second ILD 106, the source/drain contacts 112, and the gate contacts 114. The interconnect structure 150 may be electrically coupled to the source/drain contacts 112 and/or the gate contacts 114. In FIG. 22, an etch stop layer 120, a first inter-metal dielectric (IMD) layer 122, and first conductive features are formed over the second ILD 106, the source/drain contacts 112, and the gate contacts 114. The etch stop layer 120 may be formed from silicon nitride (SiN), silicon carbide (SiC), silicon oxy-nitride (SiON), silicon oxycarbide (SiOC), silicon carbonitride (SiCN), or the like. The etch stop layer 120 may include a metal oxide (e.g., aluminum oxide), a metal nitride (e.g., aluminum nitride), or the like. The etch stop layer 120 may be a single layer formed of a homogeneous material, or a composite layer including a plurality of dielectric sub-layers formed of different materials. The etch stop layer 120 may be formed by CVD, ALD, PVD, PECVD, a spin-on-dielectric process, or the like.

The first IMD layer 122 is formed over the etch stop layer 120. The first IMD layer 122 may be formed from a low-k dielectric material, such as a dielectric material having a k-value of less than about 3.9. In some embodiments, the first IMD layer 122 may be formed from an extra-low-k (ELK) dielectric material, such as a dielectric material having a k-value of less than about 2.5. In some embodiments, the first IMD layer 122 may be formed from an oxygen-containing and/or carbon-containing low-k dielectric material, such as silicon oxide, hydrogen silsesquioxane (HSQ), methylsilsesquioxane (MSQ), combinations or multiple layers thereof, or the like. The first IMD layer 122 may be deposited using an appropriate process, such as, CVD, ALD, PVD, PECVD, or the like. The material of the etch stop layer 120 has a high etch selectivity with respect to the material of the first IMD layer 122 (e.g., an etch rate of one of the materials may be greater than five times faster than an etch rate of the other of the materials). As such, the etch stop layer 120 may be used to stop the etching of the first IMD layer 122 in subsequent processing steps.

The first conductive features 125 are formed in the first IMD layer 122 and the etch stop layer 120. Openings (not separately illustrated) for the first conductive features 125 are formed in the first IMD layer 122 and the etch stop layer 120 using acceptable photolithography and etch processes. The openings may be formed using acceptable etch processes, such as wet or dry etching, reactive ion etching (RIE), neutral beam etching (NBE), the like, or a combination thereof. The etching process may include forming a patterned etch mask (not separately illustrated), such as a patterned photoresist, and then etching the first IMD layer 122 and the etch stop layer 120 using the patterned photoresist as a mask. The patterned etch mask is then removed. The openings may be patterned through the first IMD layer 122 and the etch stop layer 120 and may expose the source/drain contacts 112 and/or the gate contacts 114.

The first conductive features 125 may be formed in the openings by depositing a liner layer 124 along top surfaces of the source/drain contacts 112 and/or the gate contacts 114 and along sidewalls of the first IMD layer 122 and the etch stop layer 120. The liner layer 124 may also be deposited along top surfaces of the first IMD layer 122. A conductive fill material 126 then fills the remainder of the openings. In some embodiments, the liner layer 124 is a barrier layer, which may include titanium, titanium nitride, tantalum, tantalum nitride, or the like. The liner layer 124 may be formed by a conformal deposition process, such as CVD, ALD, PVD, or the like. In some embodiments, the liner layer 124 may further include a metal seed layer, which may include copper, and which may be formed by PVD or the like.

After forming the liner layer 124, the conductive fill material 126 is deposited to fill the remainder of the openings. Excess material of the conductive fill material 126 may also be formed along top surfaces of the liner layer 124 over the first IMD layer 122. The conductive fill material 126 may be a metallic material, which may include copper, a copper alloy, cobalt, ruthenium, tungsten, molybdenum, silver, gold, aluminum, manganese, alloys or combinations thereof, or the like. The conductive fill material 126 may be deposited by electrochemical plating (ECP), electroless plating, CVD, PVD, ALD, or the like. A planarization process, such as a CMP, may be performed to remove excess material of the liner layer 124 and the conductive fill material 126 from surfaces of the first IMD layer 122. The first conductive features 125 may be collectively referred to as metal layer M0. It should be noted that although each of the first conductive features 125 is illustrated as being located in the same cross-section, some of the first conductive features 125 might be located in different cross-sections. However, in some embodiments, neighboring or adjacent ones of the first conductive features 125 may be in the same cross-section.

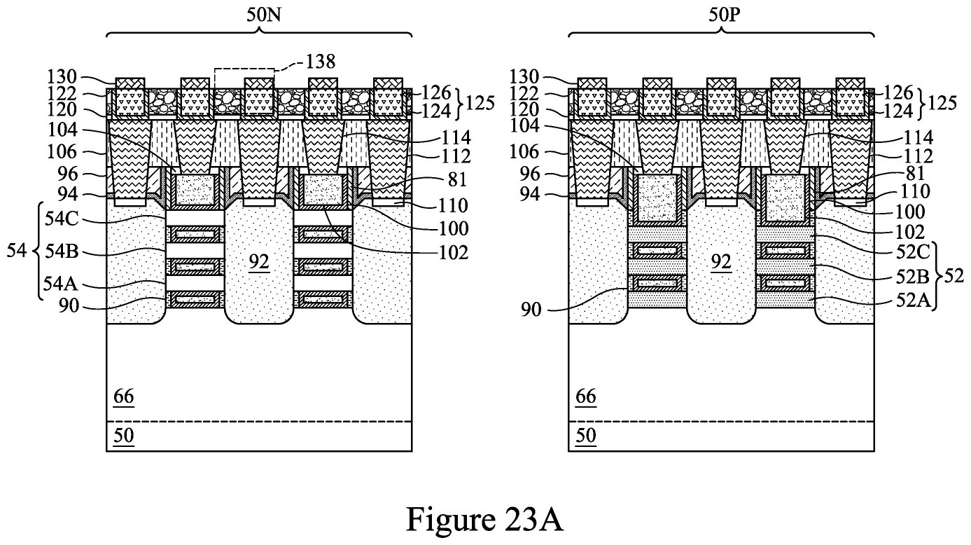

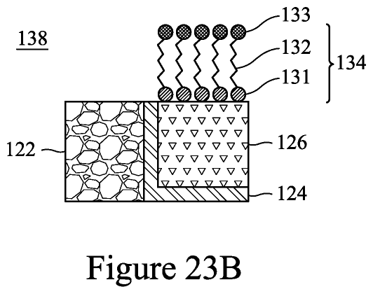

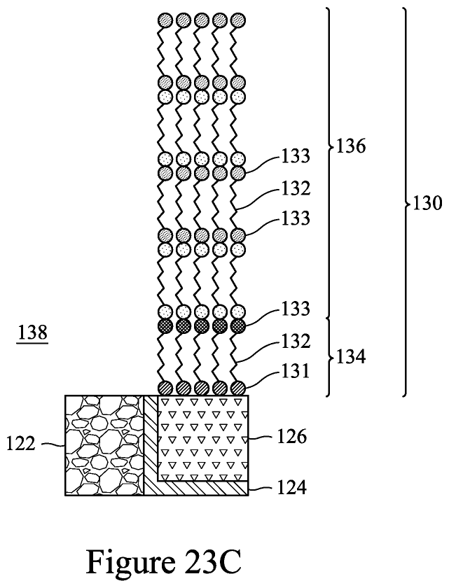

In FIGS. 23A through 23C, blocking films 130 are formed over the first conductive features 125. FIGS. 23B and 23C illustrate detailed views of region 138 of FIG. 23A. The blocking films 130 may be selectively deposited over the first conductive features 125, without being deposited on the first IMD layer 122. Further, in some embodiments, the blocking films 130 may be selectively deposited over the conductive fill material 126, without being deposited on the first IMD layer 122 or the liner layer 124. The blocking films 130 may comprise a polymer material (e.g., an organic material), which may be deposited by molecular layer deposition (MLD) or the like. The blocking films 130 may include various functional groups, such as amino groups (—NH₂), sulfhydryl groups (—SH), phosphonate groups (—PO₃H₂), carboxyl groups (—COOH). In some embodiments, the blocking films 130 may include the various functional groups along with carbon chains that include —(CH₂)ₓ— and/or —(CF₂)ₓ— units, with x ranging from about 2 to about 18. In some embodiments, the blocking films 130 may be formed from a precursor of octadecylphosphonic acid (C₁₈H₃₉O₃P, ODPA), which may have the following structure:

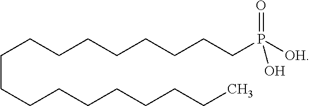 [SMILES: CCCCCCCCCCCCCCCCCCP(=O)(O)O]

FIG. 23B illustrates an initial layer 134 of the blocking films 130. As illustrated in FIG. 23B, the initial layer 134 of the blocking films 130 may include a first functional group 131, a long carbon chain 132, and a second functional group 133. The first functional group 131 may be an amino group (—NH₂), a sulfhydryl group (—SH), a phosphonate group (—PO₃H₂), or the like. The long carbon chain 132 may include —(CH₂)ₓ— and/or —(CF₂)ₓ— units, with x ranging from about 2 to about 18. The second functional group 133 may be a carboxyl group (—COOH), an amino group (—NH₂), or the like. In some embodiments, the initial layer 134 may be formed according to the following reaction: H₂O₃P—(CH₂)ₓ—NH₂+CuOH (or CoOH)→Cu(or Co)OHO₂P—(CH₂)ₓ—NH₂+H₂O. In embodiments in which the precursor includes ODPA, the initial layer 134 may be formed according to the following reaction: H₂O₃P—(CH₂)ₓ—CH₃+CuOH (or CoOH)→Cu(or Co)OHO₂P—(CH₂)ₓ—CH₃+H₂O.

FIG. 23C illustrates additional layers 136 of the blocking film 130 formed over the initial layer 134. As illustrated in FIG. 23C, the additional layers 136 of the blocking films 130 may include two of the second functional groups 133 and a long carbon chain 132. The second functional groups 133 may be carboxyl groups (—COOH), amino groups (—NH₂), or the like. The long carbon chain 132 may include —(CH₂)ₓ— and/or —(CF₂)ₓ— units, with x ranging from about 2 to about 18. In some embodiments, the additional layers 136 may be formed according to the following reactions:

Cu(or Co)OHO₂P—(CH₂)ₓ—NH₂+HOOC—(CH₂)ₓ—NH₂→Cu(or Co)OHO₂P—(CH₂)ₓ—NHOC—(CH₂)ₓ—NH₂+H₂O

Cu(or Co)OHO₂P—(CH₂)ₓ—NHOC—(CH₂)ₓ—NH₂+HOOC—(CH₂)ₓ—NH₂→Cu(or Co)OHO₂P—(CH₂)ₓ—(NHOC—(CH₂)ₓ—NH₂)₂+H₂O

Cu(or Co)OHO₂P—(CH₂)ₓ—(NHOC—(CH₂)ₓ)ₙ—NH₂+HOOC—(CH₂)ₓ—NH₂→Cu(or Co)OHO₂P—(CH₂)ₓ—(NHOC—(CH₂)ₓ—NH₂)ₙ+H₂O

Cu(or Co)OHO₂P—(CH₂)ₓ—CH₃+HOOC—(CH₂)ₓ—NH₂→Cu(or Co)OHO₂P—(CH₂)ₓ—NHOC—(CH₂)ₓ—CH₃+H₂O.

In cases in which the second functional group 132 of the initial layer 134 is an amino group, the second functional group 132 of the additional layer 136 that bonds to the second functional group 132 of the initial layer 134 is a carboxyl group. Similarly, in cases in which the second functional group 132 of an underlying additional layer 136 is an amino group, the second functional group 132 of an additional layer 136 that bonds to the second functional group 132 of the underlying additional layer 136 is a carboxyl group. In cases in which the second functional group 132 of the initial layer 134 is a carboxyl group, the second functional group 132 of the additional layer 136 that bonds to the second functional group 132 of the initial layer 134 is an amino group. Similarly, in cases in which the second functional group 132 of an underlying additional layer 136 is a carboxyl group, the second functional group 132 of an additional layer 136 that bonds to the second functional group 132 of the underlying additional layer 136 is an amino group.

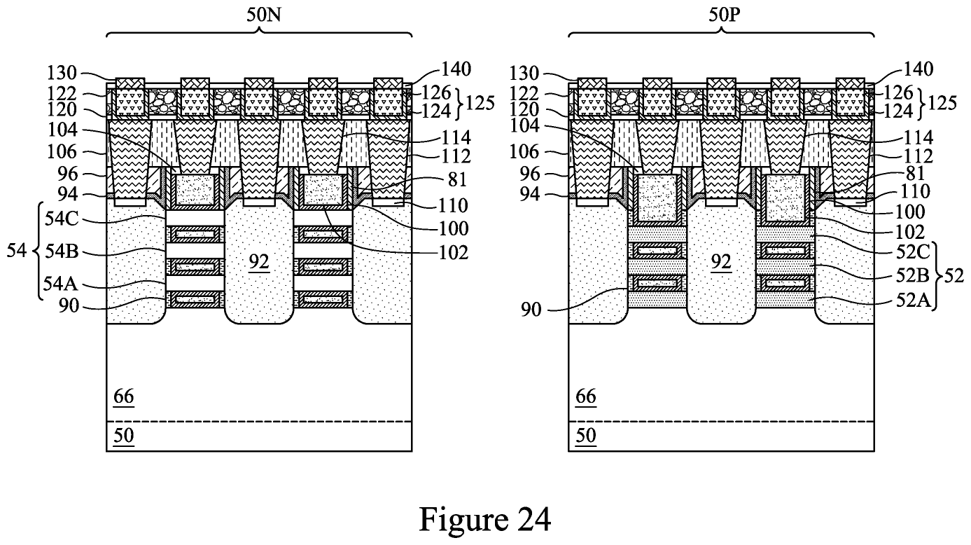

The blocking films 130 may be deposited at a temperature ranging from about 50° C. to about 400° C. and a pressure ranging from about 0.1 Torr to about 100 Torr. As illustrated in FIGS. 23A through 23C, sidewalls of the blocking films 130 may be aligned with sidewalls of the conductive fill material 126. By using MLD to deposit the blocking films 130, the thickness of the blocking films 130 may be precisely controlled. The blocking films 130 may be deposited to a thickness ranging from about 2 nm to about 7 nm. The blocking films 130 may be deposited to a thickness greater than a thickness of a subsequently deposited etch stop layer (such as the etch stop layer 140, discussed below with respect to FIG. 24) in order to prevent lateral growth of the etch stop layer over the blocking films 130. This increases the contact area of subsequently formed conductive features (such as the second conductive features 148, discussed below with respect to FIG. 29) with the first conductive features 125, which reduces contact resistance and improves device performance. Further, the blocking films 130 are formed by a self-aligned process, which prevents misalignment of the subsequently formed conductive features with respect to the first conductive features 125, reduces device defects, and improves device performance.

In FIG. 24, an etch stop layer 140 is formed over the first IMD layer 122 and the liner layer 124. The etch stop layer 140 may be selectively deposited over the first IMD layer 122, without being deposited on the first conductive features 125. In some embodiments, the etch stop layer 140 may be selectively deposited over the first IMD layer 122 and the liner layer 124, without being deposited on the conductive fill material 126. The etch stop layer 140 may be deposited by ALD or the like. The etch stop layer 140 may be a dielectric material, such as aluminum oxide (Al₂O₃), aluminum nitride (AlN), boron nitride (BN), boron carbon nitride (BCN), combinations or multiple layers thereof, or the like. The etch stop layer 140 may be deposited at a temperature ranging from about 50° C. to about 400° C. and a pressure ranging from about 0.1 Torr to about 100 Torr. The deposition process for the etch stop layer 140 may use a plasma generated from ammonia (NH₃), nitrogen (N₂), hydrogen (H₂), or a combination thereof with a plasma power ranging from about 50 W to about 1000 W. The etch stop layer 140 may be deposited to a thickness ranging from about 1 nm to about 5 nm. Forming the etch stop layer 140 to a thickness less than the prescribed range may be insufficient for the etch stop layer 140 to act as an etch stop layer and may provide inadequate protection for underlying materials, such as the first IMD layer 122. The etch stop layer 140 may act as an etch stop layer for subsequent etching processes, which protects the first IMD layer 122 from damage, increasing device performance and reducing device defects. Further, the etch stop layer 140 has a thickness less than the thickness of the blocking films 130, which prevents lateral growth of the etch stop layer 140 over the blocking films 130. This increases the contact area of subsequently formed conductive features (such as the second conductive features 148, discussed below with respect to FIG. 29) with the first conductive features 125, which reduces contact resistance and improves device performance.

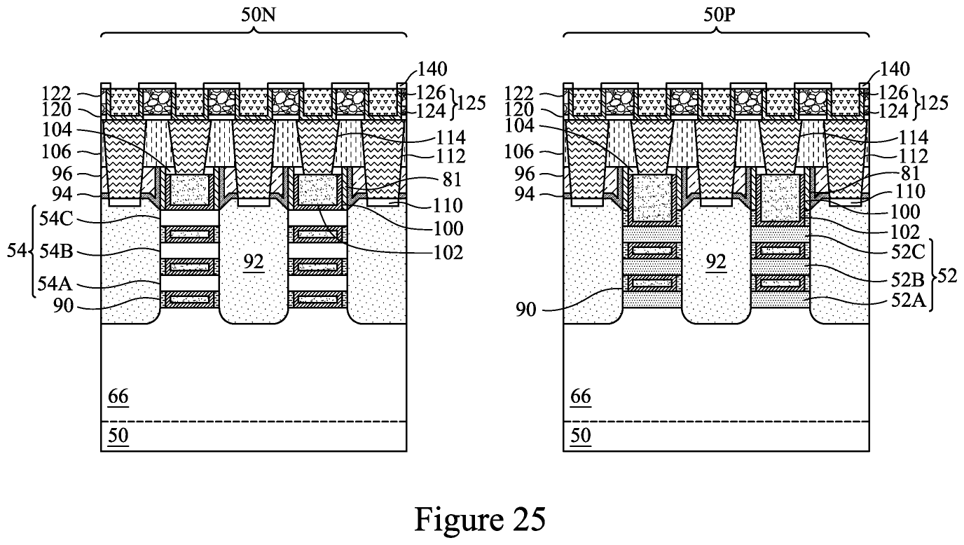

In FIG. 25, the blocking films 130 are removed. The blocking films 130 may be removed by a wet etching process, a dry etching process, a plasma process, or the like. In embodiments in which the blocking films 130 are removed by a plasma process, the plasma process may use a plasma generated from oxygen (O₂), hydrogen (H₂), nitrogen (N₂), ammonia (NH₃), or a combination thereof with a plasma power ranging from about 50 W to about 3000 W. The plasma process may be performed at a temperature of less than about 400° C. and a pressure ranging from about 0.1 Torr to about 100 Torr. As illustrated in FIG. 25, top surfaces of the conductive fill material 126 of the first conductive features 125 may be exposed after removing the blocking films 130. The processes used to remove the blocking films 130 may have a high etch selectivity with respect to the etch stop layer 140, such that the blocking films 130 are removed without significantly removing the etch stop layer 140.

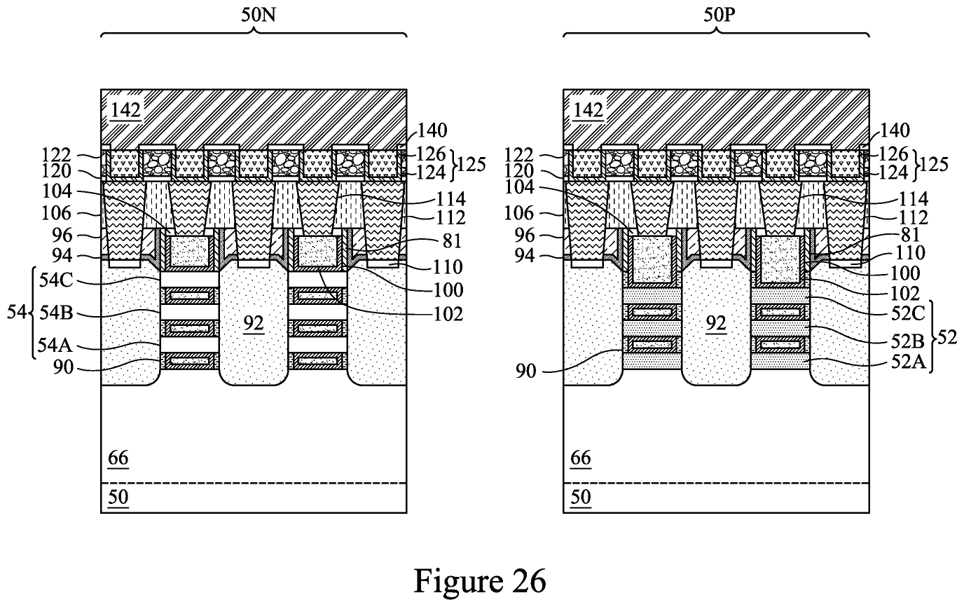

In FIG. 26, a second IMD layer 142 is formed over the first conductive features 125 and the etch stop layer 140. The second IMD layer 142 may be formed from a low-k dielectric material, such as a dielectric material having a k-value of less than about 3.9. In some embodiments, the second IMD layer 142 may be formed from an extra-low-k (ELK) dielectric material, such as a dielectric material having a k-value of less than about 2.5. The second IMD layer 142 may be formed of the same materials and by the same methods as those discussed above with respect to the first IMD layer 122.

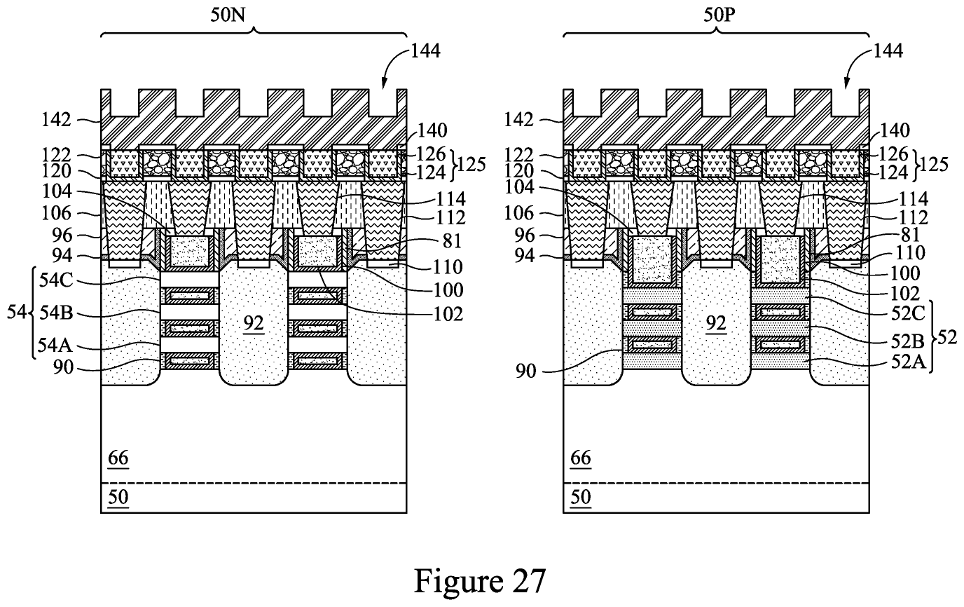

In FIG. 27, the second IMD layer 142 is etched to form first openings 144. The second IMD layer 142 may be etched using acceptable photolithography and etch processes. The first openings 144 may be formed using acceptable etch processes, such as wet or dry etching, RIE, NBE, the like, or a combination thereof. The etching process may include forming a patterned etch mask (not separately illustrated), such as a patterned photoresist, and then etching the second IMD layer 142 using the patterned photoresist as a mask. The patterned etch mask is then removed. Timed etch processes may be used to form the first openings 144 and stop the etching of the first openings 144 after the first openings 144 reach desired depths. As such, the first openings 144 may extend partially through the second IMD layer 142. As will be discussed in detail with respect to FIG. 29, below, the first openings 144 may be used to form conductive lines.

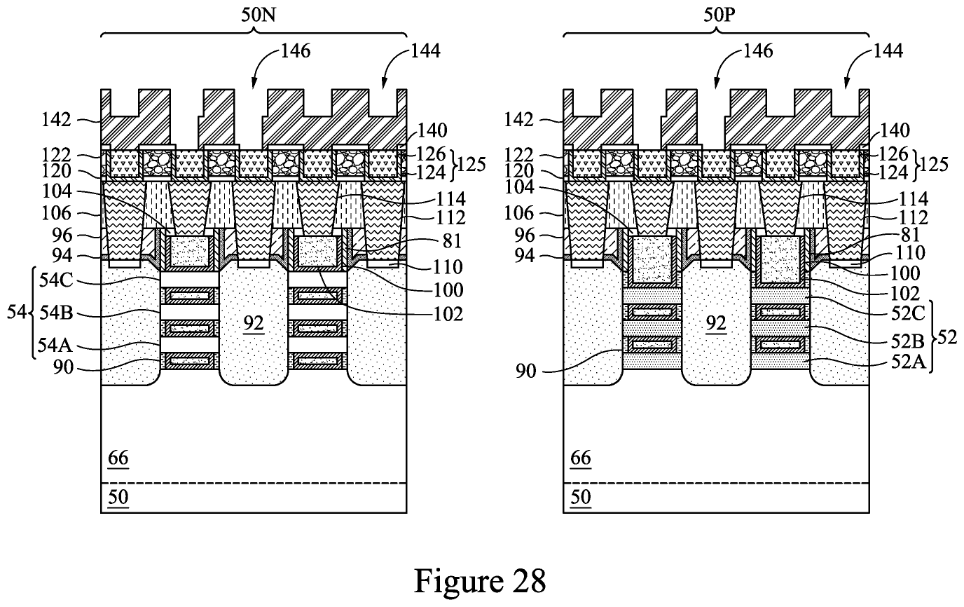

In FIG. 28, the second IMD layer 142 is etched to form second openings 146. The second IMD layer 142 may be etched using acceptable photolithography and etch processes. The second openings 146 may be formed using acceptable etch processes, such as wet or dry etching, RIE, NBE, the like, or a combination thereof. The etching process may include forming a patterned etch mask (not separately illustrated), such as a patterned photoresist, and then etching the second IMD layer 142 using the patterned photoresist as a mask. The patterned etch mask is then removed. The second openings 146 are patterned through the second IMD layer 142 and expose the first conductive features 125. The etching process used to etch the second IMD layer 142 may have a high etch selectivity with respect to the etch stop layer 140, such that the second IMD layer 142 is etched without significantly removing the etch stop layer 140. As illustrated in FIG. 28, the second openings 146 may be misaligned with the first openings 144 and the underlying first conductive features 125. The etch stop layer 140 protects the underlying first IMD layer 122 and prevents undesired etching of the first IMD layer 122. Further, the above-described processes are used to prevent the etch stop layer 140 from extending over the conductive fill material 126 of the first conductive features 125, which maximizes the area of the first conductive features 125 exposed by the second openings 146. This improves the contact area between conductive features formed in the second openings 146 and the first conductive features, reduces contact resistance, and improves device performance. As will be discussed in greater detail with respect to FIG. 29, below, the second openings 146 may be used to form conductive vias.

In FIG. 29, second conductive features 148 are formed in the first openings 144 and the second openings 146, forming an interconnect structure 150. The second conductive features 148 include conductive via portions formed in the second openings 146 in lower portions of the second IMD layer 142 and conductive line portions formed in the first openings 144 in upper portions of the second IMD layer 142. The second conductive features 148 may be formed in the first openings 144 and the second openings 146 by depositing a liner layer along top surfaces and sidewalls of the second IMD layer 142 and the etch stop layer 140 and along top surfaces of the first conductive features 125. A conductive fill material then fills the remainder of the first openings 144 and the second openings 146. In some embodiments, the liner layer is a barrier layer, which may include titanium, titanium nitride, tantalum, tantalum nitride, or the like. The liner layer may be formed by a conformal deposition process, such as CVD, ALD, PVD, or the like. In some embodiments, the liner layer may further include a metal seed layer, which may include copper, and which may be formed by PVD or the like.

After forming the liner layer, the conductive fill material is deposited to fill the remainder of the first openings 144 and the second openings 146. Excess material of the conductive fill material may also be formed along top surfaces of the liner layer over the second IMD layer 142. The conductive fill material may be a metallic material, which may include copper, a copper alloy, cobalt, ruthenium, tungsten, molybdenum, silver, gold, aluminum, manganese, alloys or combinations thereof, or the like. The conductive fill material may be deposited by electrochemical plating (ECP), electroless plating, CVD, PVD, ALD, or the like. A planarization process, such as a CMP, may be performed to remove excess material of the liner layer and the conductive fill material from surfaces of the second IMD layer 142.

The via portions of the second conductive features 148 formed in the second openings 146 in lower portions of the second IMD layer 142 may be collectively referred to as via layer VO. The conductive line portions of the second conductive features 148 formed in the first openings 144 in upper portions of the second IMD layer 142 may be collectively referred to as metal layer M1. It should be noted that although two via portions and five line portions of the second conductive features 148 are illustrated as being located in the same cross-section in the n-type region 50N and the p-type region 50P, any number of the via portions and the line portions may be located in a given cross-section. Further, although the above-described embodiments have been described in a particular context, metal layers M0 and M1, via layer VO, and an interconnect structure formed over a die comprising nanostructure FETs, various embodiments may be applied to dies comprising other types of transistors (e.g., fin field effect transistors (FinFETs), planar transistors, or the like), or other types of integrated circuit devices (e.g., resistors, capacitors, diodes, or the like), in lieu of or in combination with the nanostructure FETs and to any layers of interconnect structures.

Embodiments may achieve various advantages. For example, forming the blocking films 130 over the first conductive features 125 prevents the etch stop layer 140 from extending laterally over the first conductive features 125. This improves the contact area between the second conductive features 148 and the first conductive features 125, which lowers contact resistance and improves device performance. Moreover, the etch stop layer 140 prevents damage to the first IMD layer 122, which reduces device defects and improves device performance.

In accordance with an embodiment, a method includes forming a first dielectric layer over an integrated circuit device; forming a first conductive feature in the first dielectric layer; selectively depositing a polymer layer over the first conductive feature; selectively depositing an etch stop layer over the first dielectric layer adjacent the polymer layer; removing the polymer layer to form a first opening; and forming a second conductive feature in the first opening and electrically coupled to the first conductive feature. In an embodiment, the polymer layer is selectively deposited to a first thickness, the etch stop layer is selectively deposited to a second thickness, and the first thickness is greater than the second thickness. In an embodiment, the polymer layer is formed from an octadecylphosphonic acid (ODPA) precursor. In an embodiment, the polymer layer includes functional groups selected from a carboxyl group (—COOH) and an amino group (—NH₂). In an embodiment, the polymer layer is deposited by molecular layer deposition (MLD). In an embodiment, the first conductive feature includes a liner layer and a conductive fill material over the liner layer, the polymer layer is selectively deposited on the conductive fill material. In an embodiment, removing the polymer layer includes performing a plasma-based removal process on the polymer layer. In an embodiment, the etch stop layer includes aluminum oxide (Al₂O₃). In an embodiment, the etch stop layer includes a material selected from aluminum nitride (AlN), boron nitride (BN), and boron carbon nitride (BCN). In an embodiment, the polymer layer is bonded to the first conductive feature by a functional group selected from an amino group (—NH₂), a sulfhydryl group (—SH), and a phosphonate group (—PO₃H₂).

In accordance with another embodiment, a method includes forming a first metal feature in a first inter-metal dielectric (IMD) layer; depositing a blocking film over and physically contacting the first metal feature; depositing an etch stop layer over and physically contacting the first IMD layer; removing the blocking film; forming a second IMD layer over the etch stop layer; etching an opening in the second IMD layer to expose the first metal feature; and forming a second metal feature in the opening. In an embodiment, the blocking film includes a polymer. In an embodiment, the polymer includes one or more functional groups selected from an amino group (—NH₂), a sulfhydryl group (—SH), a phosphonate group (—PO₃H₂), and a carboxyl group (—COOH). In an embodiment, the blocking film is removed by a plasma-based process.

In accordance with yet another embodiment, a method includes performing a molecular layer deposition process to selectively deposit a blocking film over a first metal feature, the first metal feature extending through a first insulating layer; depositing an etch stop layer over and in contact with the first insulating layer; performing a plasma process to remove the blocking film; depositing a second insulating layer over the etch stop layer and the first metal feature; etching the second insulating layer to form a first opening exposing the first metal feature; and forming a second metal feature in the first opening. In an embodiment, the blocking film is deposited to a first thickness ranging from 2 nm to 7 nm, and the etch stop layer is deposited to a second thickness ranging from 1 nm to 5 nm. In an embodiment, the etch stop layer is deposited by a plasma process generated from a gas including at least one of ammonia (NH₃), nitrogen (N₂), or hydrogen (H₂) and using a plasma power ranging from 50 W to 1000 W. In an embodiment, the etch stop layer includes aluminum oxide (Al₂O₃). In an embodiment, the plasma process used to remove the blocking film uses a plasma generated from at least one of oxygen (O₂), nitrogen (N₂), hydrogen (H₂), or ammonia (NH₃), and using a plasma power ranging from 50 W to 3000 W. In an embodiment, the first metal feature includes a liner layer and a conductive fill material, the blocking film being deposited with sidewalls aligned with sidewalls of the conductive fill material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first dielectric layer over an integrated circuit device;
forming a first conductive feature in the first dielectric layer;
selectively depositing a polymer layer over the first conductive feature;
selectively depositing an etch stop layer over the first dielectric layer adjacent the polymer layer;
removing the polymer layer to form a first opening; and
forming a second conductive feature in the first opening and electrically coupled to the first conductive feature.

2. The method of claim 1, wherein the polymer layer is selectively deposited to a first thickness, wherein the etch stop layer is selectively deposited to a second thickness, and wherein the first thickness is greater than the second thickness.

3. The method of claim 1, wherein the polymer layer is formed from an octadecylphosphonic acid (ODPA) precursor.

4. The method of claim 1, wherein the polymer layer comprises functional groups selected from a carboxyl group (—COOH) and an amino group (—NH₂).

5. The method of claim 1, wherein the polymer layer is deposited by molecular layer deposition (MLD).

6. The method of claim 1, wherein the first conductive feature comprises a liner layer and a conductive fill material over the liner layer, wherein the polymer layer is selectively deposited on the conductive fill material.

7. The method of claim 1, wherein removing the polymer layer comprises performing a plasma-based removal process on the polymer layer.

8. The method of claim 1, wherein the etch stop layer comprises aluminum oxide (Al₂O₃).

9. The method of claim 1, wherein the etch stop layer comprises a material selected from aluminum nitride (AlN), boron nitride (BN), and boron carbon nitride (BCN).

10. The method of claim 1, wherein the polymer layer is bonded to the first conductive feature by a functional group selected from an amino group (—NH₂), a sulfhydryl group (—SH), and a phosphonate group (—PO₃H₂).

11. A method comprising:
forming a first metal feature in a first inter-metal dielectric (IMD) layer;
depositing a blocking film over and physically contacting the first metal feature;
depositing an etch stop layer over and physically contacting the first IMD layer;
removing the blocking film;
forming a second IMD layer over the etch stop layer;
etching an opening in the second IMD layer to expose the first metal feature; and
forming a second metal feature in the opening.

12. The method of claim 11, wherein the blocking film comprises a polymer.

13. The method of claim 12, wherein the polymer comprises one or more functional groups selected from an amino group (—NH₂), a sulfhydryl group (—SH), a phosphonate group (—PO₃H₂), and a carboxyl group (—COOH).

14. The method of claim 11, wherein the blocking film is removed by a plasma-based process.

15. A method comprising:
performing a molecular layer deposition process to selectively deposit a blocking film over a first metal feature, wherein the first metal feature extends through a first insulating layer;
depositing an etch stop layer over and in contact with the first insulating layer;
performing a plasma process to remove the blocking film;
depositing a second insulating layer over the etch stop layer and the first metal feature;
etching the second insulating layer to form a first opening exposing the first metal feature; and
forming a second metal feature in the first opening.

16. The method of claim 15, wherein the blocking film is deposited to a first thickness ranging from 2 nm to 7 nm, and wherein the etch stop layer is deposited to a second thickness ranging from 1 nm to 5 nm.

17. The method of claim 15, wherein the etch stop layer is deposited by a plasma process generated from a gas comprising at least one of ammonia (NH₃), nitrogen (N₂), or hydrogen (H₂) and using a plasma power ranging from 50 W to 1000 W.

18. The method of claim 15, wherein the etch stop layer comprises aluminum oxide (Al₂O₃).

19. The method of claim 15, wherein the plasma process used to remove the blocking film uses a plasma generated from at least one of oxygen (O₂), nitrogen (N₂), hydrogen (H₂), or ammonia (NH₃), and using a plasma power ranging from 50 W to 3000 W.

20. The method of claim 15, wherein the first metal feature comprises a liner layer and a conductive fill material, wherein the blocking film is deposited with sidewalls aligned with sidewalls of the conductive fill material.
